(19) United States
(12) Patent Application Publication
(10) Pub. No.: US 2025/0006617 A1
(43) Pub. Date: Jan. 2, 2025

(54) EMBEDDED CHIPLETS WITH BACKSIDE POWER DELIVERY NETWORK

(71) Applicant: ADEIA SEMICONDUCTOR BONDING TECHNOLOGIES INC., San Jose, CA (US)

(72) Inventors: Xu CHANG, San Jose, CA (US); Rajesh KATKAR, Milpitas, CA (US)

(21) Appl. No.: 18/401,124

(22) Filed: Dec. 29, 2023

Related U.S. Application Data
(60) Provisional application No. 63/511,555, filed on Jun. 30, 2023.

(51) Int. Cl. H01L 23/498; H01L 23/00; H01L 25/065

(52) U.S. Cl. CPC H01L 23/49838; H01L 23/49822; H01L 24/05; H01L 24/45; H01L 25/0652; H01L 2224/05024; H01L 2224/05025; H01L 2224/45005; H01L 2224/4502; H01L 2924/01014; H01L 2924/01029; H01L 2924/1427; H01L 2924/1432

(57) ABSTRACT

An assembly may include a base element comprising a base substrate having a frontside with active circuitry and a backside opposite the frontside, a first bonding layer disposed on the frontside of the base substrate and including a signal pad to convey an electrical signal to the active circuitry. The assembly may further include a first functional element comprising a first semiconductor substrate having a frontside with active circuitry and a backside opposite the frontside, a second bonding layer disposed on the frontside of the first semiconductor substrate, and a back surface of the first functional element having a first contact feature to connect to power or ground, wherein the first bonding layer is hybrid bonded to the second bonding layer.

### CROSS-REFERENCE TO RELATED APPLICATIONS

This application claims priority to U.S. Provisional Application No. 63/511,555, filed Jun. 30, 2023, titled “EMBEDDED CHIPLETS WITH BACKSIDE POWER DELIVERY NETWORK,” the disclosure of which is incorporated herein by reference in its entirety for all purposes.

### BACKGROUND

### Technical Field

This disclosure relates to semiconductor device structures and methods. In particular, some embodiments are directed to methods and structures for providing backside power delivery to embedded chiplets.

### Description of Related Art

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section.

As features in semiconductor devices continue to shrink, power delivery issues are of increasing concern. Electrical isolation issues, limitations on feature sizes due to the high density of circuit elements and interconnects, losses due to traversing large numbers of metal layers, and so forth can make it difficult to efficiently provide power to semiconductor devices. Tight spacing between interconnects can cause interference between power and signaling. Accordingly, there is a need for improved semiconductor device assemblies.

### SUMMARY

The systems, methods, and devices described herein each have several aspects, no single one of which is solely responsible for its desirable attributes. Without limiting the scope of this disclosure, several non-limiting features will now be described briefly.

In some embodiments, the techniques described herein relate to an electronic assembly including: a base element including a base substrate having a frontside with active circuitry and a backside opposite the frontside, a first bonding layer disposed on the frontside of the base substrate and including a signal pad to convey an electrical signal to the active circuitry on the frontside of the base substrate; and a first functional element including a first semiconductor substrate having a frontside with active circuitry and a backside opposite the frontside, a second bonding layer disposed on the frontside of the first semiconductor substrate, and a back surface of the first functional element having a first contact feature to connect to power or ground, wherein the first bonding layer is hybrid bonded to the second bonding layer.

In some aspects, the techniques described herein relate to an electronic assembly, further including an insulating material disposed along a side surface of the first functional element and on the first bonding layer.

In some aspects, the techniques described herein relate to an electronic assembly, wherein the insulating material includes an inorganic dielectric.

In some aspects, the techniques described herein relate to an electronic assembly, wherein the insulating material includes silicon oxide.

In some aspects, the techniques described herein relate to an electronic assembly, wherein the insulating material includes an organic dielectric.

In some aspects, the techniques described herein relate to an electronic assembly, wherein the insulating material is formed from low temperature tetraethyl orthosilicate.

In some aspects, the techniques described herein relate to an electronic assembly, further including an interconnect structure disposed on the back surface of the first functional element and electrically connected to the first contact feature.

In some aspects, the techniques described herein relate to an electronic assembly, wherein the interconnect structure includes a redistribution layer.

In some aspects, the techniques described herein relate to an electronic assembly, wherein the interconnect structure includes one or more metallization layers.

In some aspects, the techniques described herein relate to an electronic assembly, wherein the interconnect structure includes an intermediate interconnect layer and a global interconnect layer, wherein the intermediate interconnect layer is disposed near a back surface of the interconnect structure, wherein the global interconnect layer is disposed on the intermediate interconnect layer nearer to a front surface of the interconnect structure than the intermediate interconnect layer, and wherein the intermediate interconnect layer is in electrical communication with the global interconnect layer.

In some aspects, the techniques described herein relate to an electronic assembly, wherein the interconnect structure further includes an input/output (IO) pad disposed near the front surface of the interconnect structure, wherein the IO pad is in electrical communication with the global interconnect layer, and wherein the IO pad is exposed at the front surface of the interconnect structure.

In some aspects, the techniques described herein relate to an electronic assembly, further including a second functional element including a second semiconductor substrate having a frontside with active circuitry and a backside opposite the frontside.

In some aspects, the techniques described herein relate to an electronic assembly, wherein the second functional element further includes a third bonding layer disposed on the frontside of the second semiconductor substrate, wherein the third bonding layer is hybrid bonded to the first bonding layer.

In some aspects, the techniques described herein relate to an electronic assembly, wherein the backside of the second functional element is hybrid bonded to the first bonding layer, and wherein the second functional element includes a second contact feature disposed on a front surface of the second functional element.

In some embodiments, the techniques described herein relate to an electronic assembly including: a base element including a base substrate having a frontside and a backside opposite the frontside, a first bonding layer disposed on the frontside of the base substrate; a first functional element including a first semiconductor substrate having a frontside with active circuitry and a backside opposite the frontside, a second bonding layer disposed on the frontside of the first semiconductor substrate, and a back surface of the first functional element comprising a first contact feature to connect to power or ground; and a second functional element including a second semiconductor substrate having a frontside with active circuitry and a backside opposite the frontside, wherein the first bonding layer is hybrid bonded to the second bonding layer and the second semiconductor element is hybrid bonded to the base element.

In some aspects, the techniques described herein relate to an electronic assembly, wherein the backside of the second semiconductor substrate is hybrid bonded to the base element, and wherein the second functional element includes a second contact feature disposed on a front surface of the second functional element to connect to power or ground.

In some aspects, the techniques described herein relate to an electronic assembly, wherein the frontside of the second functional element is hybrid bonded to a front surface of the base substrate, and wherein a back surface of the second functional element includes a second contact feature to connect to power or ground.

In some aspects, the techniques described herein relate to an electronic assembly, wherein the first bonding layer includes a contact feature to convey an electrical signal to the active circuitry on the frontside of the base substrate.

In some aspects, the techniques described herein relate to an electronic assembly, further including an insulating material disposed along a side surface of the first functional element and on the first bonding layer.

In some aspects, the techniques described herein relate to an electronic assembly, wherein the insulating material includes an inorganic dielectric.

In some aspects, the techniques described herein relate to an electronic assembly, wherein the insulating material includes silicon oxide.

In some aspects, the techniques described herein relate to an electronic assembly, wherein the insulating material includes an organic dielectric.

In some aspects, the techniques described herein relate to an electronic assembly, wherein the insulating material is formed from low temperature tetraethyl orthosilicate.

In some aspects, the techniques described herein relate to an electronic assembly, further including an interconnect structure, the interconnect structure disposed on the backside of the first semiconductor substrate and electrically connected to the first contact feature.

In some aspects, the techniques described herein relate to an electronic assembly, wherein the interconnect structure includes a redistribution layer.

In some aspects, the techniques described herein relate to an electronic assembly, wherein the interconnect structure includes one or more metallization layers.

In some aspects, the techniques described herein relate to an electronic assembly, wherein the interconnect structure includes an intermediate interconnect layer and a global interconnect layer, wherein the intermediate interconnect layer is disposed near a back surface of the interconnect structure, wherein the global interconnect layer is disposed on the intermediate interconnect layer nearer to a front surface of the interconnect structure than the intermediate interconnect layer, and wherein the intermediate interconnect layer is in electrical communication with the global interconnect layer.

In some aspects, the techniques described herein relate to an electronic assembly, wherein the interconnect structure further includes an input/output (IO) pad disposed near the front surface of the interconnect structure, wherein the IO pad is in electrical communication with the global interconnect layer, and wherein the IO pad is exposed at the front surface of the interconnect structure.

In some aspects, the techniques described herein relate to an electronic assembly, further including: a base logic substrate having a frontside with an active region and a backside; and a base interconnect layer disposed on the frontside of the basic logic substrate, wherein the base interconnect layer is hybrid bonded to a back surface of the first semiconductor substrate.

In some aspects, the techniques described herein relate to an electronic assembly, further including an interconnect structure having a front surface and a back surface, the back surface of the interconnect structure being disposed on the backside of the base logic substrate.

In some embodiments, the techniques described herein relate to an electronic assembly including: a base element including a front surface and a back surface opposite the front surface; a first functional element including: a substrate including a frontside and a backside opposite the frontside, the frontside of the first functional element disposed on the frontside of the base element and electrically connected thereto; a second functional element including: a substrate including a frontside having an active region and a backside opposite the frontside; an interconnect structure disposed on the backside of the substrate of the first functional element and electrically connected thereto, wherein the first functional element includes power and ground connections on a backside, wherein the first functional element includes signal connections on the frontside, and, wherein the frontside of the first functional element is hybrid bonded to the front surface of the base element.

In some aspects, the techniques described herein relate to an electronic assembly, wherein the base element includes: a base die substrate having a frontside and a backside; and a base die interconnect structure disposed on the frontside of the base die substrate.

In some aspects, the techniques described herein relate to an electronic assembly, wherein the base die substrate further includes a base die active region on the frontside of the base die substrate.

In some aspects, the techniques described herein relate to an electronic assembly, wherein the base die interconnect structure includes a local interconnect layer and an intermediate interconnect layer, wherein the local interconnect layer of the base die interconnect structure is electrically connected to the base die active region, wherein the intermediate interconnect layer of the base die interconnect structure is electrically connected to the local interconnect layer of the base die interconnect structure, and wherein the intermediate interconnect layer of the base die interconnect structure is electrically connected to the interconnect structure.

In some aspects, the techniques described herein relate to an electronic assembly, wherein the interconnect structure includes a redistribution layer.

In some aspects, the techniques described herein relate to an electronic assembly, wherein the interconnect structure includes one or more metallization layers.

In some aspects, the techniques described herein relate to an electronic assembly, wherein the base die interconnect structure includes a redistribution layer.

In some aspects, the techniques described herein relate to an electronic assembly, wherein the base die interconnect structure includes one or more metallization layers.

In some aspects, the techniques described herein relate to an electronic assembly, further including an insulating material disposed along a side surface of the first functional element.

In some aspects, the techniques described herein relate to an electronic assembly, wherein the insulating material includes an inorganic dielectric.

In some aspects, the techniques described herein relate to an electronic assembly, wherein the inorganic dielectric includes silicon oxide.

In some aspects, the techniques described herein relate to an electronic assembly, wherein the insulating material includes an organic dielectric.

In some aspects, the techniques described herein relate to an electronic assembly, wherein the insulating material includes a material formed from low temperature tetraethyl orthosilicate.

In some aspects, the techniques described herein relate to an electronic assembly, wherein the interconnect structure includes an intermediate interconnect layer and a global interconnect layer, wherein the intermediate interconnect layer is disposed near a back surface of the interconnect structure, wherein the global interconnect layer is disposed on top of the intermediate interconnect layer, and wherein the intermediate interconnect layer is in electrical communication with the global interconnect layer.

In some aspects, the techniques described herein relate to an electronic assembly, wherein the interconnect structure further includes an input/output (IO) pad disposed on a top surface of the global interconnect layer, wherein the IO pad is exposed at a top surface of the interconnect structure, wherein the top surface of the global interconnect layer is a side of the global interconnect layer farthest from the first functional element.

In some aspects, the techniques described herein relate to an electronic assembly, wherein the first functional element further includes: a plurality of vias extending from the backside of the first functional element to an active region of the first functional element to electrically connect the interconnect structure to the active region of the first functional element.

In some aspects, the techniques described herein relate to an electronic assembly, further including a second functional element having a front surface and a back surface.

In some aspects, the techniques described herein relate to an electronic assembly, wherein the front surface of the second functional element is disposed on the front surface of the base element, and wherein the interconnect structure is further disposed on the backside of the second functional element.

In some aspects, the techniques described herein relate to an electronic assembly, wherein the back surface of the second functional element is disposed on the front surface of the base element.

In some aspects, the techniques described herein relate to an electronic assembly, wherein the front surface of the first functional element is hybrid bonded to the front surface of the base element, and wherein the front surface of the second functional element is hybrid bonded to the front surface of the base element.

In some aspects, the techniques described herein relate to an electronic assembly, wherein the back surface of the second functional element is hybrid bonded to the front surface of the base element.

In some aspects, the techniques described herein relate to an electronic assembly, wherein the second functional element electrically connects to at least one of power or ground via the frontside of the second functional element.

In some aspects, the techniques described herein relate to an electronic assembly, wherein the second functional element electrically connects to power or ground via the back surface of the second functional element, and wherein the second functional element includes signal and electrical contact features disposed at the front surface of the second functional element.

In some aspects, the techniques described herein relate to an electronic assembly, wherein the base element includes a base die interconnect structure, and wherein the base die interconnect structure includes an integrated voltage regulator.

In some aspects, the techniques described herein relate to an electronic assembly, wherein the first functional element receives power directly from the base die interconnect structure at a first voltage, wherein the second functional element receives power at second voltage different from the first voltage, and wherein the second functional element receives power that is routed from the base die interconnect structure to the integrated voltage regulator.

In some aspects, the techniques described herein relate to an electronic assembly, wherein the second functional element includes power and ground electrical contact features on the backside of the second functional element.

In some aspects, the techniques described herein relate to an electronic assembly, wherein the second functional element includes power and ground electrical connections on the frontside of the second functional element.

In some aspects, the techniques described herein relate to an electronic assembly, further including: a via extending from the interconnect structure to the front surface of the base element.

In some aspects, the techniques described herein relate to an electronic assembly, wherein the interconnect structure further includes a mixed signal element.

In some aspects, the techniques described herein relate to an electronic assembly, wherein the interconnect structure further includes a passive element.

In some aspects, the techniques described herein relate to an electronic assembly, further including a heat spreader disposed on the back surface of the base element.

In some aspects, the techniques described herein relate to an electronic assembly, further including: a base logic substrate having a frontside including an active region and a backside; and a base interconnect layer disposed on the frontside of the basic logic substrate, wherein the base interconnect layer is hybrid bonded to the back surface of the first functional element.

In some embodiments, the techniques described herein relate to a method including: providing a base element including: a front surface; a back surface; and base element contact features disposed on the front surface of the base element to electrically connect to a first functional element having a front surface and a back surface; bonding a front surface of the first functional element to the front surface of the base element; forming an insulating material on a side surface of the first functional element; and forming an interconnect structure on the back surface of the first functional element and the insulating material, wherein the first functional element includes power and ground electrical contact features on the back surface of the first functional element, wherein the first functional element includes signal and electrical contact features on the front surface of the first functional element, and wherein the interconnect structure is electrically connected to the power and ground electrical contact features of the first functional element.

In some aspects, the techniques described herein relate to a method, wherein bonding the front surface of the first functional element to the front surface of the base element includes hybrid bonding the front surface of the first functional element to the front surface of the base element.

In some aspects, the techniques described herein relate to a method, wherein the base element includes: a base die substrate having a frontside and a backside; and a base die interconnect structure disposed on the frontside of the base substrate.

In some aspects, the techniques described herein relate to a method, wherein the base die substrate further includes a base die active region on the frontside of the base die substrate.

In some aspects, the techniques described herein relate to a method, wherein the base die interconnect structure includes a local interconnect layer and an intermediate interconnect layer, wherein the local interconnect layer of the base die interconnect structure is electrically connected to the base die active region, wherein the intermediate interconnect layer of the base die interconnect structure is electrically connected to the local interconnect layer of the base die interconnect structure, and wherein the intermediate interconnect layer of the base die interconnect structure is electrically to the interconnect structure.

In some aspects, the techniques described herein relate to a method, wherein the interconnect structure includes a redistribution layer.

In some aspects, the techniques described herein relate to a method, wherein the interconnect structure includes one or more metallization layers.

In some aspects, the techniques described herein relate to a method, wherein the base die interconnect structure includes a redistribution layer.

In some aspects, the techniques described herein relate to a method, wherein the base die interconnect structure includes one or more metallization layers.

In some aspects, the techniques described herein relate to a method, wherein the insulating material includes an inorganic dielectric.

In some aspects, the techniques described herein relate to a method, wherein the inorganic dielectric includes silicon oxide.

In some aspects, the techniques described herein relate to a method, wherein the insulating material includes an organic dielectric.

In some aspects, the techniques described herein relate to a method, wherein the insulating material includes a material formed from low temperature tetraethyl orthosilicate.

In some aspects, the techniques described herein relate to a method, wherein the interconnect structure includes an intermediate interconnect layer and a global interconnect layer, wherein the intermediate interconnect layer is disposed near a backside of the interconnect structure, and wherein the global interconnect layer is disposed on top of the intermediate interconnect layer.

In some aspects, the techniques described herein relate to a method, wherein the interconnect structure further includes an input/output (IO) pad disposed on top of the global interconnect layer, wherein the IO pad is exposed at a top surface of the interconnect structure.

In some aspects, the techniques described herein relate to a method, wherein the first functional element includes: a first functional element active region disposed near the front surface of the first functional element; wherein the interconnect structure delivers power or ground to the first functional element active region via the back surface of the first functional element.

In some aspects, the techniques described herein relate to a method, wherein the interconnect structure includes a plurality of nano-vias extending from the back surface of the first functional element to the first functional element active region.

In some aspects, the techniques described herein relate to a method, further including: bonding a second functional element to the front surface of the base element, the second functional element having a front surface and a back surface, the second functional element bonded to the front surface of the base element via the front surface of the second functional element.

In some aspects, the techniques described herein relate to a method, wherein the front surface of the second functional element is hybrid bonded to the front surface of the base element.

In some aspects, the techniques described herein relate to a method, wherein the front surface of the first functional element is hybrid bonded to the front surface of the base element.

In some aspects, the techniques described herein relate to a method, wherein the front surface of the first functional element is hybrid bonded to the front surface of the base element, and wherein the front surface of the second functional element is hybrid bonded to the front surface of the base element.

In some aspects, the techniques described herein relate to a method, wherein the second functional element electrically connects to power or ground via the front surface of the second functional element.

In some aspects, the techniques described herein relate to a method, wherein the second functional element includes power and ground electrical connections disposed on the back surface of the second functional element, and wherein the second functional element includes signal and electrical connections disposed on the front surface of the second functional element.

In some aspects, the techniques described herein relate to a method, further including: forming an electrical interconnect extending from a top surface of the insulating material to a bottom surface of the insulating material, the bottom surface of the insulating material being in contact with the front surface of the base element.

In some aspects, the techniques described herein relate to a method, wherein the interconnect structure further includes a mixed signal element.

In some aspects, the techniques described herein relate to a method, wherein the interconnect structure further includes a passive element.

In some aspects, the techniques described herein relate to a method, further including: placing a heat spreader in thermal communication with the back surface of the base element.

In some aspects, the techniques described herein relate to a method, wherein the base element includes a base die interconnect structure, and wherein the base die interconnect structure includes an integrated voltage regulator.

In some aspects, the techniques described herein relate to a method, wherein the first functional element is configured to receive power directly from the interconnect structure at a first voltage, wherein the second functional element receives power at a second voltage different from the first voltage, and wherein the second functional element receives power that is routed from the interconnect structure to the integrated voltage regulator.

In some aspects, the techniques described herein relate to a method, further including: forming a base logic substrate having a frontside including an active region and a backside; forming a base interconnect layer disposed on the frontside of the base logic substrate; and hybrid bonding the base interconnect layer to the back surface of the first functional element.

In some aspects, the techniques described herein relate to a method, further including forming a base die interconnect structure having a front surface and a back surface, the back surface of the base die interconnect structure disposed on the backside of the base logic substrate.

In some embodiments, the techniques described herein relate to a method including: providing a base element including: a base substrate having a frontside including active circuitry and a backside opposite the frontside; and a first bonding layer disposed on the frontside of the base substrate including a contact feature to convey an electrical signal to the active circuitry; providing a first functional element including: a first semiconductor substrate having a frontside including active circuitry and a backside opposite the frontside; a first contact feature disposed on a back surface of the first functional element and configured to connect to power or ground; and a second bonding layer disposed on the frontside of the first semiconductor substrate; and hybrid bonding the first bonding layer of the base element to the second bonding layer of the first functional element.

In some aspects, the techniques described herein relate to a method, further including forming an insulating material disposed along a side surface of the first functional element and on the first bonding layer.

In some aspects, the techniques described herein relate to a method, wherein the insulating material includes an inorganic dielectric.

In some aspects, the techniques described herein relate to a method, wherein the insulating material includes silicon oxide.

In some aspects, the techniques described herein relate to a method, wherein the insulating material includes an organic dielectric.

In some aspects, the techniques described herein relate to a method, wherein the insulating material is formed from low temperature tetraethyl orthosilicate.

In some aspects, the techniques described herein relate to a method, further including forming an interconnect structure, the interconnect structure disposed on the back surface of the first functional element and electrically connected to the first contact feature.

In some aspects, the techniques described herein relate to a method, wherein the interconnect structure includes a redistribution layer.

In some aspects, the techniques described herein relate to a method, wherein the interconnect structure includes one or more metallization layers.

In some aspects, the techniques described herein relate to a method, wherein the interconnect structure includes an intermediate interconnect layer and a global interconnect layer, wherein the intermediate interconnect layer is disposed near a back surface of the interconnect structure, wherein the global interconnect layer is disposed on the intermediate interconnect layer nearer to a front surface of the interconnect structure than the intermediate interconnect layer, and wherein the intermediate interconnect layer is in electrical communication with the global interconnect layer.

In some aspects, the techniques described herein relate to a method, wherein the interconnect structure further includes an input/output (IO) pad disposed near the front surface of the interconnect structure, wherein the IO pad is in electrical communication with the global interconnect layer, and wherein the IO pad is exposed at the front surface of the interconnect structure.

In some aspects, the techniques described herein relate to a method, further including providing a second functional element including a second semiconductor substrate having a frontside including active circuitry and a backside opposite the frontside.

In some aspects, the techniques described herein relate to a method, wherein the second functional element further includes a third bonding layer disposed on the frontside of the second semiconductor substrate, wherein the third bonding layer is hybrid bonded to the first bonding layer.

In some aspects, the techniques described herein relate to a method, further including hybrid bonding the backside of the second functional element to the first bonding layer, and wherein the second functional element includes a second contact feature disposed on a front surface of the second functional element.

In some embodiments, the techniques described herein relate to a method including: providing a base element including: a base substrate having a frontside and a backside opposite the frontside; and a first bonding layer disposed on the frontside of the base substrate; providing a first functional element including: a first semiconductor substrate having a frontside including active circuitry and a backside opposite the frontside; and a second bonding layer disposed on the frontside of the first semiconductor substrate, the backside of the first semiconductor substrate including a first contact feature to connect to power or ground; providing a second functional element including: a second semiconductor substrate having a frontside including active circuitry and a backside opposite the frontside; hybrid bonding the first bonding layer to the second bonding layer; and hybrid bonding the second functional element to the first bonding layer.

In some aspects, the techniques described herein relate to a method, further including hybrid bonding the backside of the second semiconductor substrate to the base element, wherein the second functional element includes a second contact feature disposed on the frontside of the second semiconductor substrate to connect to power or ground.

In some aspects, the techniques described herein relate to a method, further including direct hybrid bonding the frontside of the second functional element to the first bonding layer, wherein the backside of the second semiconductor substrate includes a second contact feature to connect to power or ground.

In some aspects, the techniques described herein relate to a method, wherein the first bonding layer includes a contact feature to convey an electrical signal to the active circuitry.

In some aspects, the techniques described herein relate to a method, further including forming an insulating material disposed along a side surface of the first functional element and on the first bonding layer.

In some aspects, the techniques described herein relate to a method, wherein the insulating material includes an inorganic dielectric.

In some aspects, the techniques described herein relate to a method, wherein the insulating material includes silicon oxide.

In some aspects, the techniques described herein relate to a method, wherein the insulating material includes an organic dielectric.

In some aspects, the techniques described herein relate to a method, wherein the insulating material is formed from low temperature tetraethyl orthosilicate.

In some aspects, the techniques described herein relate to a method, further including forming an interconnect structure, the interconnect structure disposed on the backside of the first semiconductor substrate and electrically connected to the first contact feature.

In some aspects, the techniques described herein relate to a method, wherein the interconnect structure includes a redistribution layer.

In some aspects, the techniques described herein relate to a method, wherein the interconnect structure includes one or more metallization layers.

In some aspects, the techniques described herein relate to a method, wherein the interconnect structure includes an intermediate interconnect layer and a global interconnect layer, wherein the intermediate interconnect layer is disposed near a back surface of the interconnect structure, wherein the global interconnect layer is disposed on the intermediate interconnect layer nearer to a front surface of the interconnect structure than the intermediate interconnect layer, and wherein the intermediate interconnect layer is in electrical communication with the global interconnect layer.

In some aspects, the techniques described herein relate to a method, wherein the interconnect structure further includes an input/output (IO) pad disposed near the front surface of the interconnect structure, wherein the IO pad is in electrical communication with the global interconnect layer, wherein the IO pad is exposed at the front surface of the interconnect structure.

In some aspects, the techniques described herein relate to a method, further including: providing a base logic substrate having a frontside including an active region and a backside; providing a base interconnect layer disposed on the frontside of the basic logic substrate; and hybrid bonding the base interconnect layer to the back surface of the first semiconductor substrate.

In some aspects, the techniques described herein relate to a method, further including forming an interconnect structure having a front surface and a back surface, the back surface of the interconnect structure being disposed on the backside of the base logic substrate.

In some embodiments, the techniques described herein relate to an electronic assembly including: an interconnect structure having one or more input/output (IO) pads; a first functional element comprising a first semiconductor substrate having a frontside with active circuitry and a backside opposite the frontside, and a front surface of the first functional element having a first contact feature connected to the one or more IO pads; and a second functional element comprising a second semiconductor substrate having a frontside with active circuitry and a backside opposite the frontside, and a back surface of the second functional element having a second contact feature connected to the one or more IO pads.

In some aspects, the techniques described herein relate to an electronic assembly, wherein the first and second contact features are configured to connect to power or ground.

In some aspects, the techniques described herein relate to an electronic assembly further including a base element, wherein the first functional element and the second functional element are disposed on the base element.

In some aspects, the techniques described herein relate to an electronic assembly, wherein the base element further comprises a base substrate having a frontside with active circuitry and a backside opposite the frontside, a first bonding layer disposed on the frontside of the base substrate and a signal pad to convey an electrical signal to the active circuitry on the frontside of the base substrate.

In some aspects, the techniques described herein relate to an electronic assembly further including a second bonding layer disposed on the frontside of the first semiconductor substrate, and a third bonding layer disposed on the frontside of the second semiconductor substrate, wherein the first bonding layer is hybrid bonded to the second bonding layer, and wherein the third bonding layer is hybrid bonded to the first bonding layer.

In some aspects, the techniques described herein relate to an electronic assembly further including an insulating material disposed along a side surface of the first functional element and on the first bonding layer.

In some aspects, the techniques described herein relate to an electronic assembly, wherein the insulating material comprises an inorganic dielectric.

In some aspects, the techniques described herein relate to an electronic assembly, wherein the insulating material comprises silicon oxide.

In some aspects, the techniques described herein relate to an electronic assembly, wherein the insulating material comprises an organic dielectric.

In some aspects, the techniques described herein relate to an electronic assembly, wherein the insulating material is formed from low temperature tetraethyl orthosilicate.

In some aspects, the techniques described herein relate to an electronic assembly further including an interconnect structure disposed on the backside of the second semiconductor substrate and electrically connected to the second contact feature.

In some aspects, the techniques described herein relate to an electronic assembly, wherein the interconnect structure comprises a redistribution layer.

In some aspects, the techniques described herein relate to an electronic assembly, wherein the interconnect structure comprises one or more metallization layers.

In some aspects, the techniques described herein relate to an electronic assembly, wherein the interconnect structure comprises an intermediate interconnect layer and a global interconnect layer, wherein the intermediate interconnect layer is disposed near a back surface of the interconnect structure, wherein the global interconnect layer is disposed on the intermediate interconnect layer nearer to a front surface of the interconnect structure than the intermediate interconnect layer, and wherein the intermediate interconnect layer is in electrical communication with the global interconnect layer.

In some aspects, the techniques described herein relate to an electronic assembly, wherein the interconnect structure further comprises an input/output (IO) pad disposed near the front surface of the interconnect structure, wherein the IO pad is in electrical communication with the global interconnect layer, and wherein the IO pad is exposed at the front surface of the interconnect structure.

Various combinations of the above and below recited features, embodiments, and aspects are also disclosed and contemplated by the present disclosure.

Additional embodiments of the disclosure are described below in reference to the appended claims, which may serve as an additional summary of the disclosure.

### BRIEF DESCRIPTION OF THE DRAWINGS

These and other features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIG. 1 schematically illustrates an example semiconductor device assembly according to some embodiments.

FIG. 2 schematically illustrates a semiconductor device assembly according to some embodiments.

FIG. 3 schematically illustrates power and ground delivery paths according to some embodiments.

FIG. 4 schematically illustrates a semiconductor device assembly according to some embodiments.

FIG. 5A schematically illustrates an example of communication between a base element and a functional element according to some embodiments.

FIG. 5B schematically illustrates an example of communication between a first functional element and a second functional element.

FIGS. 6A and 6B schematically illustrate an example semiconductor device assembly according to some embodiments.

FIG. 7 schematically illustrates a top view of an example semiconductor device assembly according to some embodiments.

FIG. 8 schematically illustrates an example semiconductor device assembly according to some embodiments.

FIG. 9 schematically illustrates an example of a semiconductor device assembly according to some embodiments.

FIGS. 10A and 10B schematically illustrate an example semiconductor device assembly according to some embodiments.

FIGS. 11A and 11B schematically illustrate a direct bonding process according to some embodiments.

### DETAILED DESCRIPTION

Although several embodiments, examples, and illustrations are disclosed below, it will be understood by those of ordinary skill in the art that the disclosure described herein extends beyond the specifically disclosed embodiments, examples, and illustrations and includes other uses of the disclosure and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the disclosure. In addition, embodiments can comprise several novel features. No single feature is solely responsible for its desirable attributes or is essential to practicing the disclosure herein described.

Backside power delivery can address several problems related to increased density and reduced feature sizes by separating power delivery from signal routing, for example so that power delivery takes place via the backside of a semiconductor device and signal routing takes place via the frontside of the semiconductor device. However, backside power delivery can be challenging to implement. In a semiconductor device that makes use of functional elements (e.g., chiplets), it can be advantageous to provide backside power delivery to some functional elements while using frontside power delivery for other functional elements. As used herein, the term functional element can comprise an integrated device die with active circuitry (e.g., one or more transistors). For example, certain functional elements, such as those used for central processing unit (CPU), graphical processing unit (GPU), and so forth can be made using advanced process nodes with very small feature sizes, while other functional elements, for example communication circuitry, can be made on older process nodes with larger feature sizes, and backside power delivery may provide only limited benefit. Some embodiments herein can enable easier and/or lower cost deployment of backside power in devices using multiple functional elements. In some cases, different functional elements made on a same process technology node can employ different power delivery methods. For example, a CPU may use backside power delivery, while static random-access memory (SRAM) can be made on the same technology node but may use frontside power delivery, or vice versa. In some cases, frontside power delivery can be well-suited to functional elements that have a regular structure. For example, memory functional elements (e.g., SRAM) can have a regular arrangement of transistors or other circuitry components, which can simplify power and signal routing as compared to a functional element with a less regular layout, such as a CPU or GPU.

As described herein, an element (e.g., a functional element and/or base element as described herein, each of which may comprise semiconductor elements in various embodiments) can have a front surface and a back surface. An element can include a substrate having a frontside and a backside. An active region can be included in or on the substrate at or near the frontside of the substrate (e.g., closer to the frontside than the backside). Interconnects can be disposed on top of the active region. The active region can include active circuitry such as, for example, transistors. The active region can also be referred to as a logic region or logic layer.

In conventional semiconductor devices, signal transmission and power delivery both take place through the frontside of the device. However, as device features continue to shrink, it is increasingly difficult to provide both power and signal through the frontside of a device. For example, as semiconductor devices become increasingly dense and complex, with each new advanced process node increasing the number of transistors or compute cells per unit area, the number of metal layers that include signal and power (or ground) lines to feed into these transistors also tends to increase, effectively increasing the path length of wires that carry power and/or signal. The increased density of transistors in an active device region can result in a corresponding increased density of power and signal circuitry. To accommodate this increased density, the cross-sectional areas of vias and/or other circuitry can be reduced. However, this can result in higher impedance and increased power losses. Shrinking the cross-sectional area and/or increasing the length of power lines, for example, can result in significant power losses due to the high resistance of the thin copper typically used for frontside power delivery. For example, devices can be designed to accommodate power delivery losses (e.g., voltage drops) of about 10% from the power supply during transmission through the metal layers to the active device region. However, significantly larger drops can be seen at smaller or more advanced manufacturing nodes, especially when there is a large number of metal layers (e.g., about 10, about 15, about 20, or even more). In some processes, metal interconnects can comprise alternative materials such as cobalt, for example in lower back end of line (BEOL) levels, which can reduce power losses. However, the benefits of using other conductive materials are limited, and a different approach may be needed to address power and signal delivery obstacles as semiconductor device features continue to shrink. Moreover, power lines occupy significant real estate on the front side of a device. This means that a semiconductor device may be significantly larger in area than its active device region in order to have sufficient area for the power and signal transmission lines to coexist on the frontside of the device.

Backside power delivery can relieve some of the problems associated with the scaling of semiconductor devices to smaller process nodes. For example, backside power delivery can alleviate congestion on the frontside by eliminating or reducing the need to route power via the frontside. Backside power delivery can enable wider and thicker power delivery and/or signal transmission lines. Backside power delivery can reduce the electrical path length between the power supply and the active device region. In some embodiments, backside power delivery can be used to reduce the number of metal layers that carry signals on the frontside of a device, thereby reducing the path length traveled by signals. Such lines can have lower impedance, which can reduce power losses and/or improve signal integrity. Additionally, even without increasing the cross-sectional area of lines, backside power delivery circuitry can improve signal integrity because, for example, power delivery circuitry can be relatively far away from signal transmission circuitry, which can reduce the potential for power transmission to interfere electromagnetically with signal transmission.

In addition to reduced losses and improved signal integrity, backside power delivery can be used as a tool to enable designers to create more compact devices. As mentioned above, semiconductor devices can be larger than is otherwise necessary for the active device region when power and signal circuitry are both on the same side of the device. Such design decisions can play an increasingly important role in scaling as moving to smaller, more advanced technology nodes offers diminishing returns.

As used herein, the term backside power delivery, backside power delivery network, frontside power, and frontside power delivery network can generally be understood to include power, ground, or both.

Traditional integrated circuit designs are monolithic, in which multiple functional circuit blocks can be provided on a common chip or integrated device die. However, this approach can have several drawbacks. In some cases, a design with multiple functional elements (e.g., chiplets) can be used instead of a monolithic design. In a functional element design, multiple functional elements (e.g., chiplets) can be integrated together to form an electronic assembly. Functional elements can be selected to optimize a semiconductor device for a particular purpose, for example. The use of functional elements can improve yield and reduce costs. For example, in a monolithic design, an integrated circuit can be relatively large. If there is a defect in the integrated circuit, the entire integrated circuit may be unusable, have reduced performance, have unusable portions (for example, a CPU core may be non-functional, some memory may be non-functional, etc.), and so forth. The area of an individual functional element can be smaller than the area of a monolithic integrated circuit that includes the features of more than one functional element. Thus, there can be a lower likelihood that an individual functional element contains an unacceptable number of defects or defects in unacceptable locations. Functional elements can be selected and binned so that only known-good functional elements are used in manufacturing a functional element-based integrated circuit (e.g., a semiconductor device that uses chiplets). Functional element designs can reduce costs by enabling manufacturing processes to be tailored to the needs of a particular functional element. For example, a functional element used to perform CPU, GPU, or other computationally intensive tasks can be made using a more advanced manufacturing process, while other components such as cache (e.g., level three cache), input/output circuitry, communications circuitry, and so forth can be made on older processes or in a manner otherwise different from some other components, which may have higher yields, simpler manufacturing processes, lower costs, and so forth. As discussed in more detail herein, advanced technologies such as backside power delivery may be used in some functional elements and may not be used in other functional elements within the same system on a chip (SOC).

The use of functional elements can simplify designs and reduce the resources needed to design new semiconductor devices. For example, using functional element designs, parts of the semiconductor device can be reused while other parts can be updated. For example, an SOC device that includes CPU, GPU, and communications circuitry can be updated with a different CPU while the GPU and communications circuitry are unchanged. Functional elements can also enable relatively easy customization of semiconductor devices. For example, a semiconductor device maker may wish to offer two versions of an SOC with many shared components but which have, for example, different amounts of memory, different acceleration elements (e.g., encryption acceleration chiplets), different numbers and/or types of CPU cores, and so forth.

SOCs can offer many benefits. However, as discussed above, there are many challenges associated with the use of functional elements. Accordingly, there is a need for methods of forming functional element-based semiconductor devices that take advantage of technological advances such as backside power delivery where it is beneficial while also accommodating functional elements that do not take advantage of backside power delivery.

In some embodiments, a semiconductor device assembly (also referred to herein as “assembly” or “electronic assembly”) can comprise a base element (also referred to as a base die) and one or more functional elements. In some embodiments, the base element can be an interposer with limited functionality. For example, an interposer base element can include interconnect layers, redistribution layers, and the like, but may not include active circuitry such as, for example, logic, communications, memory, or other similar functionality. In some embodiments, a base element can comprise a chip or integrated device die that includes various functionality. For example, the base element can include memory (e.g., SRAM), logic, communications, and/or other functionality. In some embodiments, the semiconductor device assembly can comprise at least one dummy element. For example, the dummy element can be configured to include a plurality of vias or can be configured for thermal or heat spreading purposes.

In some embodiments, the base element can comprise a base element substrate, base element logic, and a base element interconnect structure. In some embodiments, the base element interconnect structure can include a plurality of layers. For example, the base element interconnect structure can include local interconnect layers, intermediate interconnect layers, or both. In some embodiments, contact pads can be disposed on a top surface of the base element and can be in electrical communication with the intermediate interconnect layers, which in turn can be in contact with the local interconnect layers, which can in turn be in contact with the base element logic (e.g., active circuitry). In some embodiments, the interconnect structure can include a redistribution layer. As discussed above, in some embodiments, the base element can be an interposer. In such embodiments, the base element may not have base element logic or may have only limited base element logic (e.g., less than 20%, less than 15%, or less than 10% of the frontside of the base element can comprise active circuitry).

Interconnect layers can be subdivided into local, intermediate, global (and in some cases, semi-global) interconnects. The different interconnect levels can indicate, for example, signal propagation distances supported by the interconnect level. However, while such terms are commonly used, there may not be set definitions. Generally, local, intermediate, and global interconnect levels are based on different sets of layout rules and dimensions (e.g., minimum metal pitches, metal thickness, etc.) and may have different RC delays. For example, RC delay values can decrease from local to intermediate to global interconnect levels.

The critical dimensions for different interconnect levels can vary between technology nodes. For example, a 10 nm technology node may have local interconnect levels with metal pitches of from about 35 to about 45 nm, intermediate interconnect levels with metal pitches about 50 to about 115 nm, semi-global interconnect levels with metal pitches of about 160 nm to about 180 nm, and global interconnect levels with still greater metal pitches. As another example, a 4 nm technology node may have local interconnect levels with metal pitches of about 25 to about 40 nm, intermediate interconnect levels with metal pitches of about 70 to about 80 nm, and global interconnect level with metal pitches of about 700 nm to about 750 nm. In some embodiments, local interconnect levels can have critical dimensions that require the use of extreme ultraviolet lithography, sub-lithographic patterning, or other advanced lithography techniques, while intermediate interconnect levels may use single exposure lithography.

In some embodiments, where smaller RC delay interconnect levels are not accessible, the distance an interconnect may reach may be extended using, for example, buffers, restorers, and/or other circuitry at various points along a long interconnect.

In some embodiments, wafer fabrication of one or more functional elements and a base element can include local and some intermediate interconnects. Global wiring can then be deposited after bonding and reconstitution. This fabrication approach can reduce fabrication costs, fabrication time, etc. as compared to the fabrication of typical wafers, which are fabricated with local, intermediate, and global interconnects/wiring.

As used herein, the term global interconnects can refer to the thickest, widest, and most separated interconnects, intermediate interconnects can refer to interconnects that are thinner and/or more densely packed than global interconnects, and local interconnects can refer to interconnects that are thinner and/or more densely packed than intermediate interconnects and global interconnects. Global interconnects can be electrically connected to intermediate interconnects, which in turn can be electrically connected to local interconnects. Local interconnects can be electrically connected to an element (e.g., to the active circuitry of an element) to provide power, ground, and/or signal connections.

Typically, global interconnects can be found nearest the surface (e.g., the front surface) of a semiconductor element, and can be connected to conductive contact features (e.g., contact pads) configured to connect to an external device (e.g., an integrated device die, a package substrate, etc.). Global interconnects can comprise one, two, three, four, or more interconnect layers. Global interconnects can be characterized by their relatively low resistance, relatively low RC time constant, and so forth. Global interconnect layers can be used for various purposes, such as for clock distribution, power distribution, long distance communications, and so forth. Local interconnects can be the bottommost interconnect layer or layers closest to the active region of an element (e.g., closest to the frontside of the element). Local interconnects can be characterized by their relatively small width, relatively tight pitch, and so forth. In some embodiments, local interconnects can be used for signal and/or power transmission across relatively small distances. For example, local interconnects may be used for local connection of transistor elements within a macro cell or sub-circuit. Intermediate interconnects can be larger than local interconnects but smaller than global interconnects. Intermediate interconnect layers can be characterized by a relatively low density of vias (for example, as compared to local interconnect layers). Intermediate interconnects may, for example, be used for communications with a large circuit block and/or between small circuit blocks. The relatively low density within intermediate interconnect layers can result in the availability of empty space. In some embodiments, circuit elements can be placed in the intermediate interconnect layers. For example, power management circuitry, mixed signal devices, passives such as capacitors, resistors, and inductors, and so forth can be included in one or more intermediate layers. In some embodiments, such circuit elements can span more than one intermediate interconnect layer. An interconnect layer (e.g., a global interconnect layer, intermediate interconnect layer, and/or local interconnect layer) can also be referred to as a metallization layer. A metallization layer can comprise an insulating material (e.g., an inorganic dielectric such as silicon oxide) with embedded conductive traces and/or vias. The interconnect layers can be connected to one another by vias that extend perpendicularly to the layers.

In some embodiments, the base element can include features for power delivery, power regulation, and so forth. In some embodiments, different functional elements can have different voltage requirements. In some embodiments, the power supplied to a semiconductor device assembly can be different from the power requirements of a functional element or base element. For example, the functional element and/or circuitry within the base element may operate at a different voltage than the voltage supplied to the semiconductor device assembly. In some embodiments, the base element can include one or more integrated voltage regulators which can be used to define one or more power domains. In some embodiments, an integrated voltage regulator (IVR) can be included in a base element interconnect structure. For example, in some embodiments, an IVR can comprise a small portion of the base element transistors and the associated base element local and/or intermediate interconnects. In some embodiments, power delivery can be shared between functional elements within the same power domain, as discussed in more detail below. In some embodiments, the base element can include multiple integrated voltage regulators. In some embodiments, the base element can include various passive components, such as inductors, capacitors, resistors, and so forth.

In some embodiments, a functional element can receive some or all power from the base element directly. For example, such an approach may be desirable if the base element and the functional element share a same voltage.

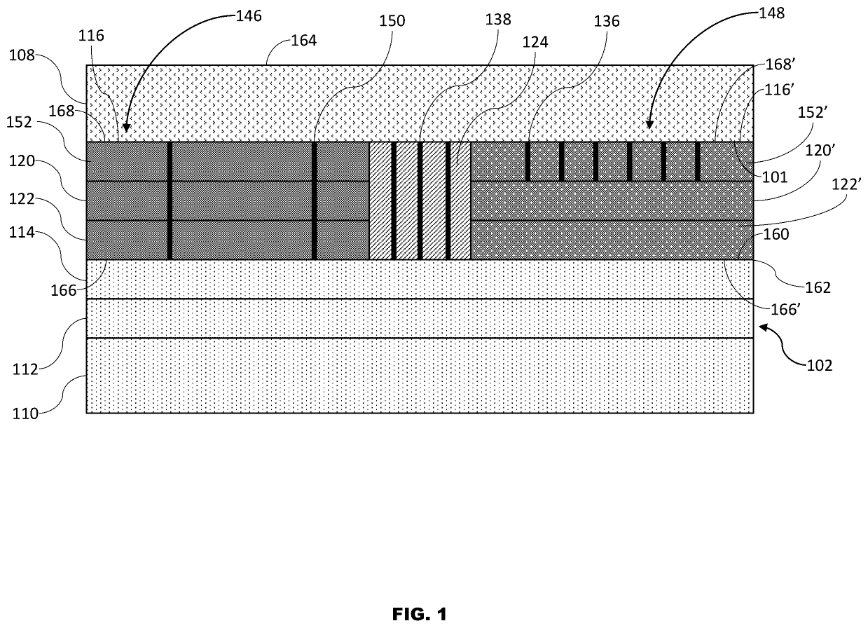

FIG. 1 is a block diagram that illustrates an example semiconductor device assembly according to some embodiments. As shown in FIG. 1, the semiconductor device assembly can include a base element 102, interconnect structure 108, first functional element 146, and second functional element 148. The first functional element 146, the second functional element 148, or both can comprise integrated circuit dies or chiplets having active circuitry formed therein. The base element 102 can include a base element substrate 110, an active region 112, and a base element interconnect structure 114. The first functional element 146 can include an active region 120, an interconnect structure 122, and a functional element substrate 152. Similarly, the second functional element 148 can include an active region 120′, an interconnect structure 122′, and a functional element substrate 152′. For example, in various embodiments, the substrates 110, 152, 152′ can comprise semiconductor portions (e.g., silicon or other suitable semiconductor) of the respective elements 102, 146, 148, and the active regions 112, 120, 120′ can comprise device portions of the respective elements 102, 146, 148 that include active circuitry (e.g., transistors) patterned or formed in or on the semiconductor portions. The interconnect structures 114, 122, 122′ can comprise back-end-of-line (BEOL) structures deposited over the respective active regions 112, 120, 120′. For example, the interconnect structures 114, 122, 122′ can comprise inorganic dielectric material(s) (e.g., silicon oxide, silicon nitride, etc.) with embedded conductors (such as embedded conductive vias and/or traces).

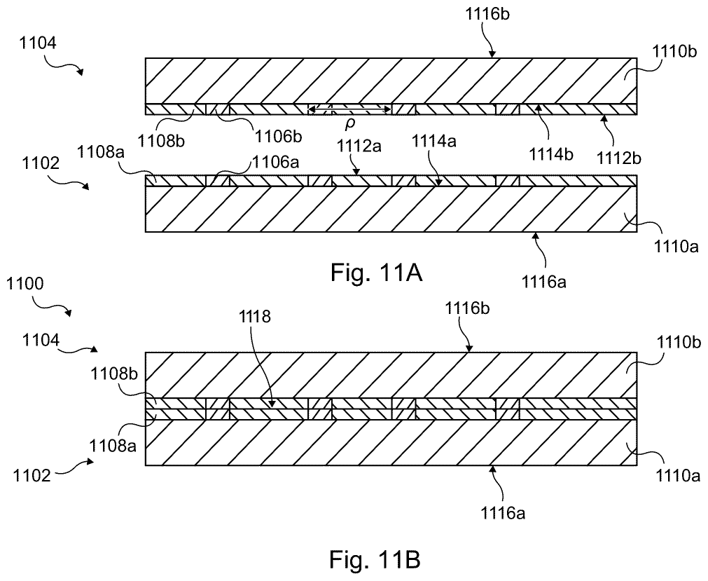

The first functional element 146 and second functional element 148 can be disposed on a front surface 160 of the base element 102. For example, a front surface 166 of the first functional element 146, a front surface 166′ of the second functional element 148, or both can be bonded (e.g., hybrid bonded) to the front surface 160 of the base element 102 along a bonding interface 162. For example, in some embodiments, the front surface 160, 166, 166′ of the base element 102, the first functional element 146, and/or the second functional element 148, respectively, can have contact features (see, e.g., FIGS. 11A-11B) disposed thereon for making electrical contact between the base element 102 and a functional element 146, 148. In some embodiments, signals can be provided through the contact features (e.g., signal pads disposed on the frontside of a base substrate and configured to convey an electrical signal to active circuitry on the frontside of the base substrate).

An insulating material 124 can be disposed at least between the first functional element 146 and the second functional element 148. An interconnect structure 108 can be disposed on a back surface 168, 168′ of the first functional element 146 and the second functional element 148, respectively. As described in more detail below, the interconnect structure 108 can include input/output pads disposed at a front surface 164 of the interconnect structure 108. The front surface 164 can be an exposed or partially exposed surface. The interconnect structure 108 can comprise one or more interconnect layers which can be, for example, global interconnects, intermediate interconnects, or both. The semiconductor device assembly of FIG. 1 can include through substrate vias (TSVs) 136, through insulator vias 138, and/or through substrate vias (TSVs) 150. The vias 136, 138, and 150 can enable electrical connection between the interconnect structure 108, base element 102, and functional elements 146, 148, as described herein. Although not shown in FIG. 1, the interconnect structures 122, 122′, 114, 108 can additionally or alternatively include conductive traces embedded in an insulating material to laterally or horizontally route signals and/or power.

In some embodiments, the interconnect structure 108 can be bonded (e.g., hybrid bonded) to functional elements and/or to the insulating material 124. In some embodiments, the interconnect structure 108 can be deposited on the functional elements and/or the insulating material. In some embodiments, circuitry for delivering power/ground to the active circuitry or a functional element can be removed or substantially removed from the frontside of the active region (e.g., from the functional element's interconnect layers) and power/ground can instead be delivered substantially or entirely via the back surface of the functional element, for example by way of direct metal contacts, nano-vias, or micro-vias leading from the back surface of the functional element to the active region of the functional element. In some embodiments, global interconnects and/or intermediate interconnects may not be included in the base element and/or functional elements. For example, in some embodiments, input/output (IO) pads, global interconnects, and/or intermediate interconnects can be included in the interconnect structure 108 and vias can be used to connect to functional elements, a base element, and so forth. In some embodiments, a functional element can be fabricated with signal connections on the front surface. In some embodiments, a base element can be fabricated with one or more interconnect levels (e.g., local and/or intermediate interconnects) near the front side and may not include global interconnects, IO pads, or both.

In some embodiments, the insulating material can be an inorganic dielectric. In some embodiments the insulating material can be an organic dielectric. In some embodiments, the insulating material can be silicon oxide or silicon nitride. In some embodiments, the insulating material can be formed using a low temperature tetraethyl orthosilicate (TEOS) process. The insulating material 124 can be a gap fill dielectric between adjacent functional elements. Forming the insulating material 124 can be challenging because, for example, the insulating material 124 can be relatively thick (e.g., about 20 micrometers or more). It can be important that the insulating material 124 is free or substantially free of voids, cracks, and/or other defects. It can also be important to employ a process that does not result in excessive wafer warping. In some embodiments, chemical vapor deposition can be performed at relatively low temperatures using TEOS.

As mentioned above, in some embodiments a semiconductor device assembly can include functional elements configured for frontside power delivery, backside power delivery, or a mix of functional elements, some of which are configured for frontside power delivery and others of which are configured for backside power delivery.

In the example embodiment of FIG. 1, the first functional element 146 is configured for frontside power delivery and the second functional element 148 is configured for backside power delivery. As illustrated in FIG. 1, the vias 136 extend from a back surface 168′ of the second functional element 148 to the active region 120′ of the second functional element 148. The vias 136 can provide power and ground from the interconnect structure 108 to the second functional element 148 (e.g., to transistors within the active region 120′ of the second functional element 148). The vias 138 can extend from a back surface 101 of the interconnect structure 108 to the front surface 160 of the base element 102, for example to the base element interconnect structure 114. Power, ground, and/or signal connections can be made from the vias 138 to the active region 112 via electrical interconnects (e.g., lateral traces) in the base element interconnect structure 114. In some embodiments, the base element interconnect structure 114 can include intermediate interconnects and local interconnects, as discussed in more detail herein.

In some embodiments, the functional element substrate 152′ can undergo a chemical mechanical polishing (CMP) process. In some of embodiments, depending upon the backside power delivery technology being used, the thickness of the functional element substrate 152′ after polishing can be from about 0 nm (e.g., the functional element substrate 152′ can be entirely or almost entirely removed) to about 5 micrometers, to about 10 micrometers, or to about 20 micrometers. For example, the thickness of the functional element substrate 152′ can be from about 300 nm to about 500 nm or from about 2 micrometers to about 5 micrometers. Accordingly, the vias 136 can be direct metal vias or contacts, nano-TSVs, or micro-TSVs. In some embodiments, when the functional element substrate 152′ is completely removed, shallow trench isolation features of the active region 120′ can be used as a CMP stop. In some embodiments, when the thickness of the functional element substrate 152′ after polishing is in a nanometer or micrometer range, a thin SiGe layer or any other suitable dielectric layer (e.g., oxide, buried oxide, etc.) may be used as an etch stop layer between the active region 120′ and an original bulk substrate the second functional element 148 was built on.

In some embodiments, frontside power can be provided by way of wire bonds to the front surface of the base element 102 (e.g., to wire bonding pads of the base element 102). The wires can electrically connect to a region outside the chiplets. The interconnect layers can convey power and ground from wire bonding pads to the circuitry of the device. However, wire bonding can result in long electrical path lengths (which can result in, for example, voltage drops, inductance loops, and so forth), increased semiconductor device assembly size, and so forth. Moreover, power and ground connections can compete with signal connections for limited space.

In some embodiments, the first functional element 146 can have vias 150 that extend from a front surface 166 of the first functional element 146 to a back surface 168 of the first functional element 146. The vias 150 can provide several advantages. For example, in the absence of vias that go through functional elements, signals that travel to and/or from the base element 102 would be constricted to travel paths that avoid the functional elements. For example, signals could travel through the vias 138 in the insulating material 124 between functional elements. In some embodiments, such traversals may not present a significant limitation. For example, if the base element 102 is an interposer that does not include the active region 112, or that includes only minimal logic in the active region 112, traversing around the functional elements may not present a significant challenge or limitation. However, if there is significant signal processing within the base element 102 (e.g., within the active region 112 of the base element 102), restricting signal flow to only through the vias 138 in the insulating material 124 could significantly limit performance as available signal routing paths can be significantly limited (for example, because there may only be limited space between functional elements and/or because the space between functional elements has limited or no availability because it is used to facilitate high speed and/or high bandwidth communications between functional elements).

While illustrated with TSVs passing through the first functional element 146, which can be configured for frontside power delivery, it will be appreciated that such TSVs can also be provided in a functional element configured for backside power delivery. While the vias 150 extend through the interconnect structure 122, active region 120, and functional element substrate 152 in FIG. 1, it will be appreciated that other configurations are possible. For example, in some embodiments, the vias 150 may extend partially through the interconnect structure 122 instead of all the way through the interconnect structure 122.

In some embodiments, a base element can be an interposer with no or limited active circuitry. In some embodiments, the base element can include active circuitry such as logic, memory, and so forth. An active circuitry region of a base element can be referred to herein as a functional region. In some embodiments, functional elements can be arranged on top of the base element in a variety of advantageous manners. For example, a functional element that includes a CPU die can be placed on the base element above a location that includes memory. The memory can be, for example, a level three cache for the CPU die. By placing the CPU die functional element on top of a memory functional region of the base element, relatively high speed, high bandwidth, and/or low latency can be achieved. In some embodiments, thermal considerations can inform the placement of functional elements on the base element. For example, if a base element includes a GPU region, it may be desirable not to place a CPU or GPU functional element on top of the GPU region of the base element in order to avoid concentrating functional elements and base element functional regions with high heat output too closely to one another.

In some embodiments, a front surface of a functional element can be disposed on a front surface of a base element. In some embodiments, the functional element can include a plurality of contact features disposed on the front surface of the functional element. The contact features of the functional element can be in electrical communication with the contact features of the base element. In some embodiments, the front surface of the base element and/or the front surface of the functional element can comprise a bonding surface, and the front surface of the functional element can be bonded to the base element. For example, in some embodiments, the functional element can be hybrid bonded to the base element. For example, the front surface of the functional element can be bonded (e.g., hybrid bonded) to the front surface of the base element. Direct bonding (e.g., hybrid bonding) are discussed in more detail herein, for example with reference to FIGS. 11A and 11B.

Although the backside 116′ of the second functional element substrate 152′ is illustrated to be the same as the back surface 168′ of the second functional element 148 in FIG. 1 (e.g., a surface comprising silicon with vias exposed), the sides need not be the same. For example, an interconnect layer or bonding layer can be deposited over the backside 116′ of the second functional element substrate 152′ as part of the process of forming the second functional element 148 and the back surface 168′ of the second functional element 148 can include an oxide layer with conductive pads at the back surface 168′.

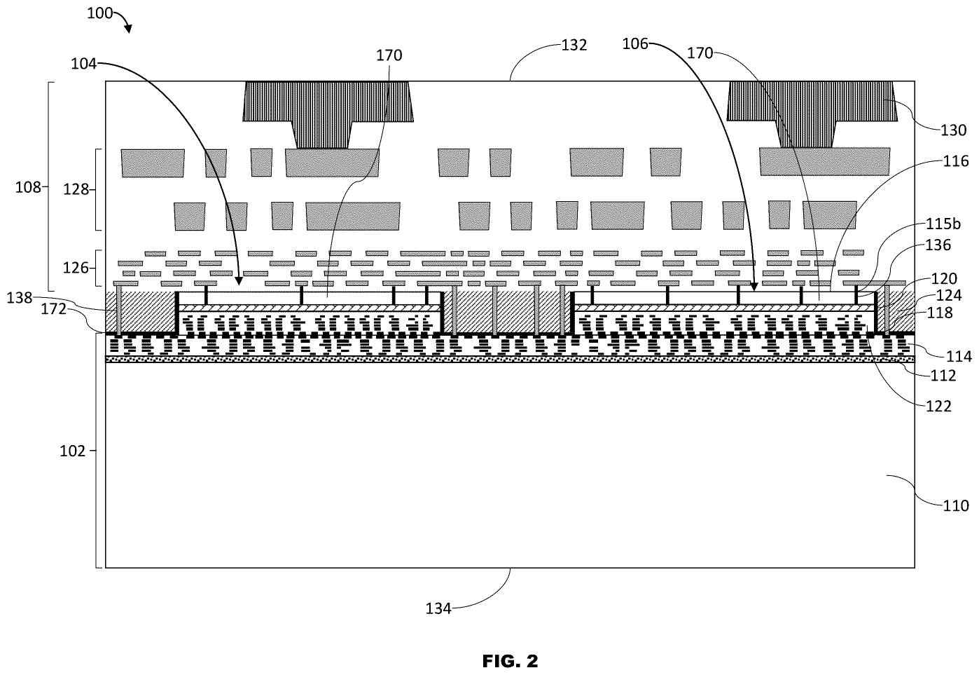

FIG. 2 illustrates an example semiconductor device assembly 100 according to some embodiments. As shown in FIG. 2, an assembly 100 can include a base element 102, a first functional element 104, a second functional element 106, and an interconnect structure 108. The assembly 100 can have a front surface 132 and a back surface 134. The base element 102 can include a base element substrate 110 (e.g., a semiconductor portion), a base element active region 112 (which can include active circuitry such as transistors), and a base element interconnect structure 114. The first functional element 104 and second functional element 106 can each include a substrate 170 having a backside 116 and a frontside 118. The first functional element 104 and the second functional element 106 can each include an active region 120 (which can include active circuitry such as transistors) formed on the substrate 170 and an interconnect structure 122. The first and second functional elements 104, 106 can be bonded (e.g., hybrid bonded) to the base element 102 at bonding interface 172. The first functional element 104 and second functional element 106 can be surrounded on respective side surfaces by one or more insulating materials 124. The insulating material 124 can comprise one or more insulating layers. For example, in some embodiments, the insulating material can comprise silicon oxide. In some embodiments, the insulating material 124 can comprise multiple layers. For example, the insulating material 124 can comprise a first dielectric material layer (such as silicon nitride or silicon oxide) that conformally coats the elements 104, 106, and a second dielectric material layer (such as silicon oxide) that fills or substantially fills the space between the elements 104, 106. The region 108 can include intermediate interconnect layers 126, global interconnect layers 128, and input/output (IO) pads 130 configured to electrically connect to an external device (e.g., by way of a direct bonding method or by way of solder balls or other electrical connectors). In a backside power delivery configuration, the first functional element 104 and the second functional element 106 can include vias 136 (e.g., nano-vias) that extend from the backside 116 of substrate 170 to the active region 120. In some embodiments, the vias 136 can be vias that do not extend all the way through the functional element. The assembly 100 can include vias 138 that extend through the insulating material 124 to electrically connect the intermediate interconnect layers 126 of the interconnect structure 108 to the base element interconnect structure 114.

In some embodiments, power/ground can be delivered substantially or entirely to the first functional element 104 and second functional element 106 via the back surfaces of the first functional element 104 and second functional element 106 by way of the intermediate interconnect layers 126 and/or global interconnect layers 128. In some embodiments, the intermediate interconnect layers 126 and/or global interconnect layers 128 of the interconnect structure 108 can act as intermediate and/or global interconnects for the assembly 100. For example, the intermediate interconnect layers 126 and/or global interconnect layers 128 can be used to provide power, ground, clock distribution, communications between adjacent functional elements, long distance communications across the assembly 100, and so forth.

In some embodiments, the substrate 170 can have a thickness of 0 nm or about 0 nm (e.g., the substrate 170 may be removed or almost completely removed), about 300 nm to about 500 nm, or about 2 micrometers to about 5 micrometers, or more or less. When the substrate 170 has a thickness of 0 nm or about 0 nm (e.g., is completely or almost completely removed), shallow trench isolation features can be used as a CMP stop, and the substrate 170 can become non-continuous remnants between the shallow trench isolation features. In some embodiments, the substrate 170 can be completely removed. In some embodiments, direct power, ground, and/or signal paths can be provided through functional elements.

As described above with reference to FIG. 1, in some embodiments the vias 136 can extend farther than is illustrated in FIG. 2. For example, in some embodiments, the vias 136 may extend through the active region 120 and through or partially through the interconnect structure 122.

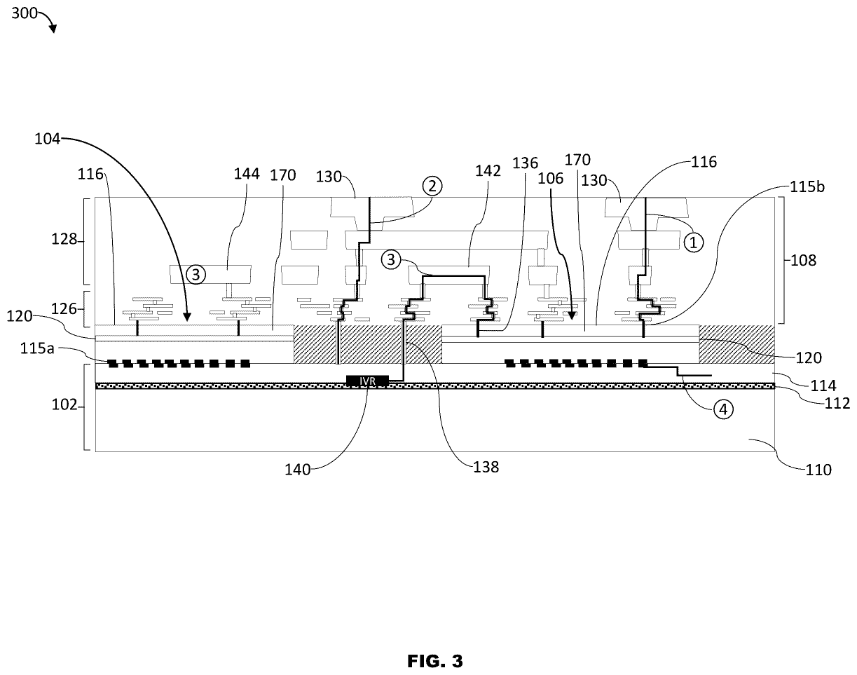

FIG. 3 illustrates examples of various power and ground delivery paths according to some embodiments. The assembly 300 shown in FIG. 3 is similar to the assembly 100 of FIG. 2, but the assembly 300 includes an integrated voltage regulator (IVR) integrated in the base element. As shown in FIG. 3, power/ground can be provided directly to the backside 116 of a substrate 170 of a first functional element 104 or second functional element 106, as indicated by circle 1. The electrical path can traverse from the IO pads 130, through the global interconnect layers 128, through the intermediate interconnect layers 126, to contact features 115b, to the vias 136, where it can be carried through a portion of the second functional element 106 to the active region 120 of the second functional element 106. Thus, power can be provided to the active region 120 of the second functional element 106 from the backside, which can offer various advantages as described herein, such as enabling the use of thicker interconnects, reduced density of frontside interconnects of functional element 106, reduced interconnect path length, and so forth.

In some embodiments, power can be provided directly to the base element 102. As shown in the path indicated by circle 2, power can be delivered from the IO pads 130 to the global interconnect layers 128, from the global interconnect layers 128 to the intermediate interconnect layers 126, then subsequently to the interconnect structure 114 of the base element 102 through the vias 138. Power that is routed to the base element 102 can be used to provide power to the base element 102 (e.g., to the active region 112 of the base element 102). Power that is routed to the base element 102 can, additionally or alternatively, be routed to one or more elements, such as first functional element 104 and/or second functional element 106. For example, power can be received at a first voltage via the path indicated by circle 2. Base element 102 can include an integrated voltage regulator (IVR) 140. The integrated voltage regulator 140 can be configured to receive the first voltage and to output a second voltage. The second voltage can be delivered to the backside of an element, such as first functional element 104 and/or second functional element 106, by traversing the path indicated by circle 3, passing from the integrated voltage regulator 140 to the vias 138, then to the intermediate interconnect layers 126 to the global interconnect layers 128, then back to the intermediate interconnect layers 126 and to the element 104 and/or 106 through the vias 136. As shown in FIG. 3, a first metal portion 142 can be electrically connected to a second metal portion 144 within a layer of the global interconnect layers 128. Thus, the first metal portion 142 and second metal portion 144 can be at the same voltage, for example the second voltage. Connections between different metal portions within an interconnect layer can reduce the amount of routing required to and from integrated voltage regulators within the interconnect structure 108 of the base element 102. For example, shared power supply lines can be used to provide power to neighboring elements. In some embodiments, the second voltage may be an output of the integrated voltage regulator 140. In some embodiments, the second voltage may be delivered to an SOC chip power delivery network that may comprise the intermediate interconnect layers 126 and/or the global interconnect layers 128. The SOC chip power delivery network may provide power to multiple functional elements (e.g., 104 and 106) from their backsides and may provide power to other portions of the base elements. Similarly, clock signals generated in circuits in base element 102, or clock signals received from an IO pad through a similar path as highlighted by circle 3 and buffered by circuits in element 102 can be delivered to an SOC chip clock delivery network that may comprise the intermediate interconnect layers 126 and/or the global interconnect layers 128 and may provide clocks to one or more functional elements (e.g., functional elements 104 and 106) from their backsides. In some embodiments, the chip clock delivery network may provide clocks to other portions of the base elements. In some embodiments, power and/or clock signal may be directly supplied (not shown in FIG. 3) from an IO pad to an SOC chip power/clock distribution network that may comprise the global interconnect layers 128 and/or the intermediate interconnect layers 126, which may provide power/clock supplies to one or more functional elements from their backsides and/or to circuits in the base element 102. As indicated by circle 4, in some embodiments, power can be delivered from the interconnect structure 114 of the base element 102 to the frontside of an element, such as first functional element 104 and/or second functional element 106. For example, even in an element designed for backside power delivery, it may be desirable to provide at least some power via the frontside of the element.

In some embodiments, the contact features 115a, 115b can be conductive features or structures exposed on the front or back surface of a functional element. For example, contact feature 115a can comprise a copper pad at least partially embedded in a dielectric material at a front or back surface of a functional element, and contact feature 115b can comprise an exposed end of a via 136 extending through a functional element. The contact features can be directly bonded to opposing features, or conductive interconnects can be deposited over the conductive features to make contact.

Although the disclosed embodiments above involve the discussion of power being delivered along the illustrated pathways, it should be appreciated that the pathways can be used for power or ground. For example, the pathways can provide electrical potentials to elements (e.g., functional elements, a base element, etc.). The electrical potentials can be at a non-zero voltage or at ground (e.g., at zero volts).

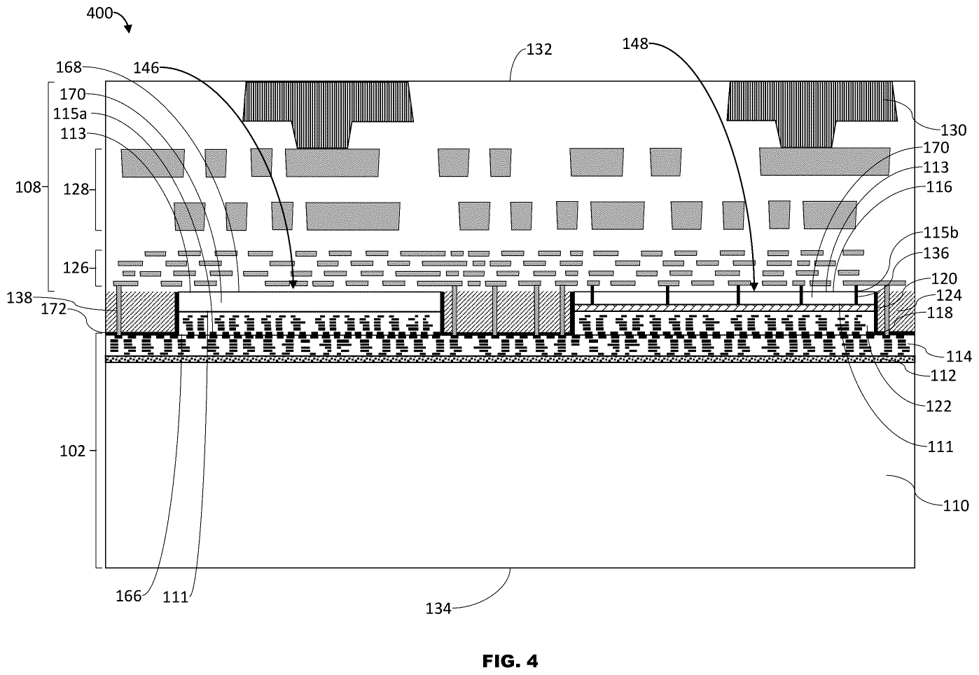

As discussed above, in some cases, it can be desirable to use a mix of elements (e.g., chiplets), some of which use backside power delivery and some of which use frontside power delivery. FIG. 4 illustrates an example embodiment of an assembly according to some embodiments. The assembly 400 is generally similar to the assembly 100 of FIG. 2 and assembly 300 of FIG. 3. However, unlike FIGS. 2 and 3, in which the first functional element 104 and second functional element 106 were both configured for backside power delivery, FIG. 4 includes first functional element 146 configured for frontside power delivery and a second element configured 148 configured for backside power delivery. For example, power and ground connections can be provided on a front surface of the first functional element 146. For example, the front surface 166 of the first functional element 146 can include contact features to provide electrical contact to active circuitry of the first functional element 146. The first functional element 146 and/or the second functional element 148 can be bonded (e.g., hybrid bonded) to the base element 102.

In some embodiments, the assembly 400 can include an interconnect structure 108 having one or more input/output (IO) pads 130, a first functional element 146, and a second functional element 148. The first functional element 146 can comprise a first semiconductor substrate 170 having a frontside 111 with active circuitry and a backside 113 opposite the frontside 111.

The front surface 166 of the first functional element 146 can have a first contact feature 115a connected to the one or more IO pads 130. Power can be provided to the first functional element 146 via the IO pads 130 to the global interconnect layers 128 and then to the intermediate interconnect layers 126. The intermediate interconnect layers 126 can provide electrical power to the base element interconnect structure 114 of the base element 102 through the vias 138. Power can be provided from the base element interconnect structure 114 (e.g., via intermediate layers of the base element interconnect structure 114) to the front surface 166 of the first functional element 146 (e.g., the first contact feature 115a at the frontside 111 of the first functional element 146).

The second functional element 148 can comprise a second semiconductor substrate 170 having a frontside 111 with active circuitry and a backside 113 opposite the frontside 111. A back surface 168 of the second functional element 148 can have a second contact feature 115b connected to the one or more IO pads 130.

Power can be provided to the second functional element 148 via the IO pads 130 to the global interconnect layers 128 and then to the intermediate interconnect layers 126, to the backside 113 of the second functional element 148 (e.g., the second contact feature 115b) to the vias 136, where it can be carried through a portion of the second functional element 148 to the active region 120 of the second functional element 148. In some embodiments, the intermediate interconnect layers 126 can be deposited over the exposed ends of the vias 136 (e.g., to make electrical contact between corresponding contact features in the intermediate interconnect layers 126 and the back surface of the functional element), with the second contact feature 115b comprising an exposed end of a via 136. Although the disclosed embodiments above involve the discussion of power being delivered, it should be appreciated that the pathways can be used for power or ground. In some embodiments, intermediate interconnect layers 126 can be directly bonded to the back surfaces of the functional elements.

In some embodiments, different elements (e.g., chiplets) can communicate with one another via local and intermediate interconnect levels of the base element interconnect structure 114 of the base element 102. For example, a first element can be a CPU chiplet and a second element can be a memory chiplet (e.g., an SRAM chiplet). In some embodiments, the first element and the second element can be configured with a high density of contact pads near one or more edges of the element. The contact pads can be, for example, contact pads for hybrid bonding to the base element 102. The base element 102 can have, in the base element interconnect structure 114, a high density of interconnects to facilitate signal transmission and reception between adjacent elements (e.g., between a CPU chiplet and an SRAM chiplet). Accordingly, in some embodiments, it can be desirable to limit or eliminate circuitry of the base element 102 in the space between elements (e.g., the space between chiplets) so as to maximize the number of interconnects available to facilitate communication between neighboring elements.

In some embodiments, the base element can include various functionality. For example, a base element can include circuitry for providing memory, computing capabilities (e.g., CPU, GPU, etc.), and so forth.

In some embodiments, the base element 102 can include an active region 112. The active region 112 can provide various functionality, such as memory, GPU, CPU, acceleration, and so forth.

In some embodiments, high speed, high bandwidth, and/or low latency communications between functional elements (e.g., between chiplets) and/or between a functional element and the base element (e.g., a functional region of a base element) can be provided. For example, such communications circuitry can be important when there is a large amount of data transfer between one element and another element, for example to write to or load from memory (e.g., an SRAM cache). In some embodiments, communication between functional elements (e.g., chiplets) can take place via interconnects provided by a base element. As discussed in more detail herein, in some embodiments, the base element can include various components such as, for example, integrated voltage regulators, functional areas (e.g., SRAM, CPU, GPU, encryption accelerators, encoding/decoding accelerators, and/or other active and/or passive components). In some embodiments, such features can be placed such that they do not undesirably limit communication between elements. For example, depending upon the communication needs between two elements, the circuitry connecting the two elements can have more or less functionality (including, for example, no functionality) other than providing interconnects between functional elements.

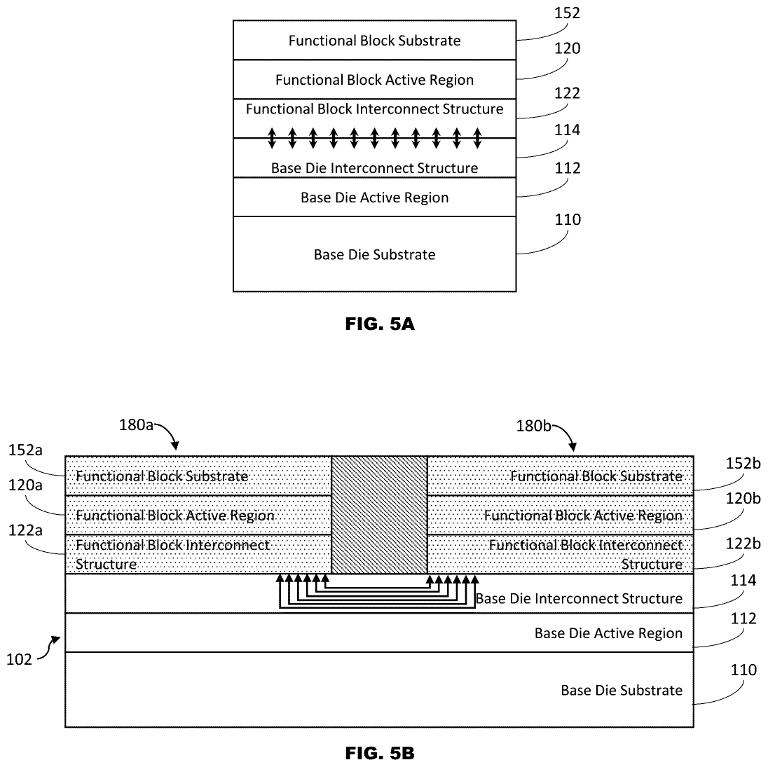

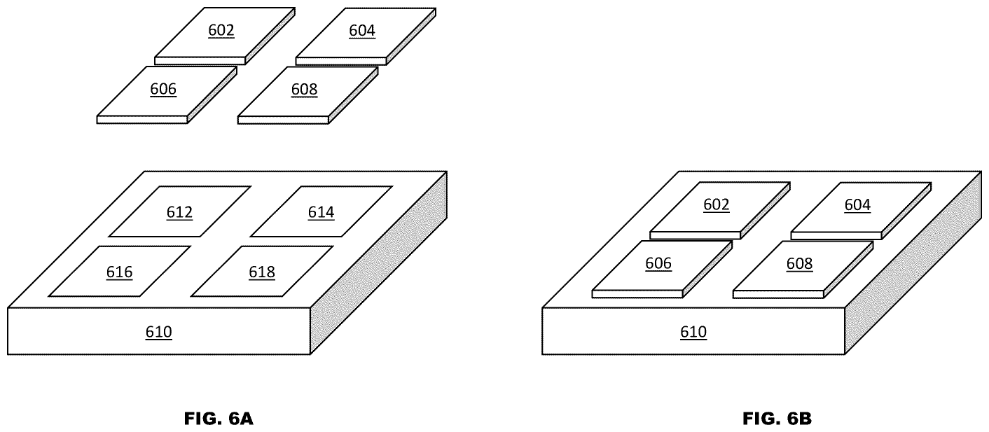

FIG. 5A illustrates an example of communication between a base element and a functional element according to some embodiments. As shown in FIG. 5A, the base element can include a base element substrate 110, an active region 112, and a base element interconnect structure 114. The functional element can include an interconnect structure 122, active region 120, and functional element substrate 152. The interconnect structure 122 and base element interconnect structure 114 can be in electrical communication with one another. For example, the interconnect structure 122 and base element interconnect structure 114 can include contact features such as contact pads, vias, and so forth. In some embodiments, the front surface of the functional element can be bonded (e.g., hybrid bonded) to the front surface of the base element.

FIG. 5B illustrates an example of communication between a first functional element 180a and a second functional element 180b. A front surface of the first functional element 180a can be bonded (e.g., hybrid bonded) to a front surface of a base element 102. A front surface of the second functional element 180b can be bonded (e.g., hybrid bonded) to the front surface of the base element 102. The base element 102 can include a base element substrate 110, active region 112, and base element interconnect structure 114. The first functional element 180a can include a first functional element interconnect structure 122a, a first functional element active region 120a, and a first functional element substrate 152a. The second functional element 180b can include a second functional element interconnect structure 122b, a second functional element active region 120b, and a second functional element substrate 152b. In some embodiments, the functional elements 180a and 180b may not have substrates 152a and 152b. The first functional element 180a and second functional element 180b can be separated by a gap. The gap can, in some embodiments, be filled with one or more insulating materials as described herein. The first functional element 180a and second functional element 180b can communicate with one another through the base element interconnect structure 114 of the base element. In some embodiments, the region of the base element where the interconnect structure 114 is used to facilitate communication between the first functional element 180a and the second functional element 180b can be kept relatively free of circuitry used for purposes other than to facilitate communication between functional elements.

As discussed briefly above, in some embodiments, a base element can include a logic layer. In some embodiments, the base element can comprise an interposer that provides electrical connections but does not provide other functionality or that provides only limited functionality. For example, in some embodiments, the base element of FIG. 5B may not have an active region.

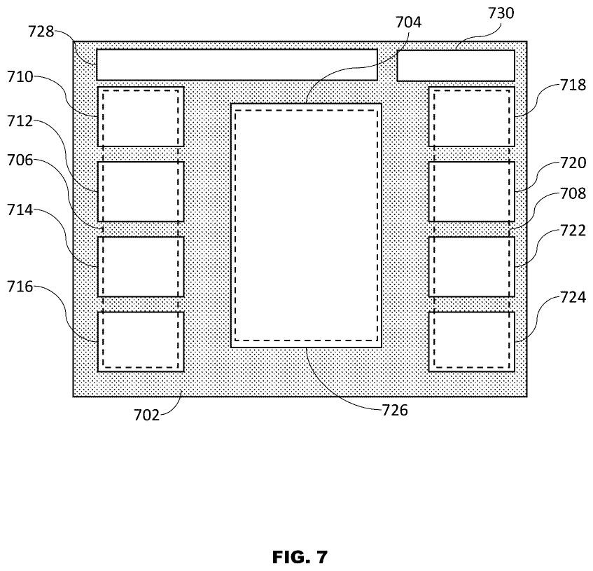

FIGS. 6A and 6B illustrate an example semiconductor device assembly according to some embodiments. The device assembly can include a base element 610. The base element 610 and have functional regions 612-618. Functional elements 602-608 can be disposed on a front surface of the base element 610. For example, in some embodiments, the functional elements 602-608 can be bonded (e.g., hybrid bonded) to the front surface of the base element 610. In some embodiments, intermediate and global interconnects of the combined SOC chip are disposed above the functional elements 602-608 (not shown in FIG. 6B). In some embodiments, one or more of the functional elements 602-608 can be configured for backside power delivery. In some embodiments, one or more of the functional elements 602-608 can be configured for frontside power delivery. In some embodiments, at least one of the functional elements 602-608 can be configured for backside power delivery and at least one other of the functional elements 602-608 can be configured for frontside power delivery. Although the functional elements 602-608 are shown to be hybrid bonded to and aligned with the functional regions 612-618 of the base element 610, they can be partially or substantially offset with respect to the functional regions 612-618. In some embodiments, one or more functional elements can overlap with one or more functional regions of the base element. In some embodiments, at least one of the functional elements can be a dummy element or a passthrough element (e.g., providing only wiring and TSVs) or one or more passive elements with or without passthrough wiring.

While FIGS. 6A and 6B depict a semiconductor device assembly in which the number of functional regions in the base element is the same as the number of functional elements bonded to the front surface of the base element 610, it will be appreciated that the number of functional regions in the base element 610 and the number of functional elements is not necessarily the same.

The functional regions 612-618 and the functional elements 602-608 can include various functionality. For example, the functional regions 612-618 and the functional elements 602-608 can include memory (e.g., SRAM), CPU, GPU, and/or other functionality. In some embodiments, functional regions and functional elements can be arranged to prevent or limit stacking of elements that each have high thermal dissipation demands. For example, in some embodiments, a CPU functional element may not be stacked on top of a GPU functional region. In some embodiments, functional regions and functional elements can be arranged to facilitate communication between different functional elements, between different functional regions, and/or between functional elements and functional regions. As an example, the functional element 602 can be a GPU or CPU core, and the functional region 612 can be an SRAM. The functional element 602 can disposed on top of the functional region 612. For example, the functional region 612 can be a cache or other memory for the functional element 602. In some embodiments, one or more of the functional regions can be the same as or similar to one or more of the functional elements. For example, an SRAM element can stack on top of an SRAM to expand the total SRAM of the SOC. Similarly, a CPU/core can be stacked directly on another CPU/core to provide a dense multi-core structure.

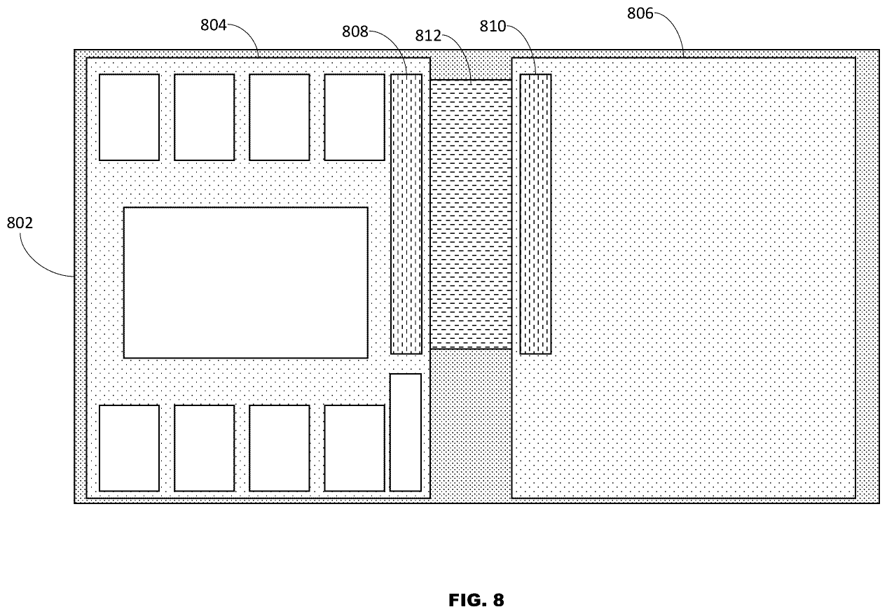

FIG. 7 illustrates a top view of an example semiconductor device assembly according to some embodiments. In FIG. 7, the base element 702 can include a functional region 704, a functional region 706, and a functional region 708. In FIG. 7, the functional regions of the base element 702 are illustrated with dashed rectangles. A functional element (e.g., a chiplet) can include features 710-730. The features 710-730 can include various types of functionality, such as CPU cores, GPU cores, SRAM, high speed communications circuitry, and so forth. For example, features 710, 712, 714, and 716 can be CPU cores, and functional region 706 can be SRAM. For example, features 718, 720, 722, and 724 can be CPU cores, and functional region 708 can be SRAM. The feature 726 can be SRAM, and the functional region 704 can be a CPU core. The features 728 and 730 can be, for example, communications interfaces. As shown in FIG. 7, there can be a one-to-one correspondence between a feature of the functional element and a functional region of the base element, for example feature 726 and functional region 704. Other ratios are also possible. For example, in the illustrated example, four CPU cores are paired with one SRAM functional region (706 or 708). In some cases, a feature of the functional element may not have a corresponding functional region in the base element, such as the features 728 and 730 of the illustrated example.

While depicted as a single functional element (e.g., a single chiplet) in FIG. 7, it will be appreciated that, in some embodiments, the features 710-730 can be separate functional elements (e.g., separate chiplets) that are each bonded (e.g., directly bonded) to the base element 702.

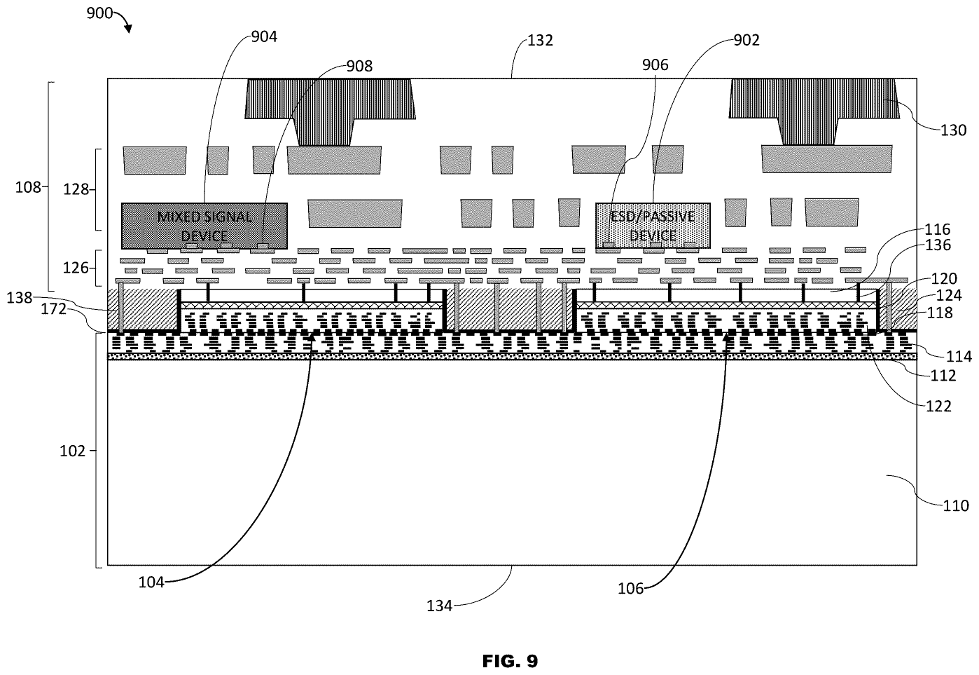

As mentioned above, it can be desirable to have high speed, high bandwidth, and/or low latency communication between functional elements. FIG. 8 illustrates an example semiconductor device assembly according to some embodiments. The assembly can include a base element 802, functional element 804, and functional element 806. In some embodiments, one or both of the functional element 804 and the functional element 806 can be configured for backside power delivery. In some embodiments, the functional element 804 and/or the functional element 806 can be bonded (e.g., hybrid bonded) to the base element 802. The functional element 804 can include a region of high density contact features 808. The functional element 806 can include a region of high density contact features 810. The base element 802 can include interconnects 812 that can be used to connect the high density contact features 808 and high density contact features 810. In some embodiments, there may be little or no additional circuitry or functionality in the base element region of the interconnects 812.

In some embodiments, it can be desirable to include additional features within an interconnect structure. For example, an interconnect structure can include passive devices, electrostatic discharge (ESD) protection devices, mixed signal devices, and so forth. An ESD/passive device can include, for example, resistors, capacitors, diodes (e.g., Zener diodes, transient voltage suppressor diode, etc.), fuses, relays, reverse bias diodes, inductors, and so forth. In some embodiments, a mixed signal device can be a device configured for both analog and digital processing. For example, a mixed signal device can include a digital to analog converter, analog to digital converter, error checking and correction circuitry, and so forth.

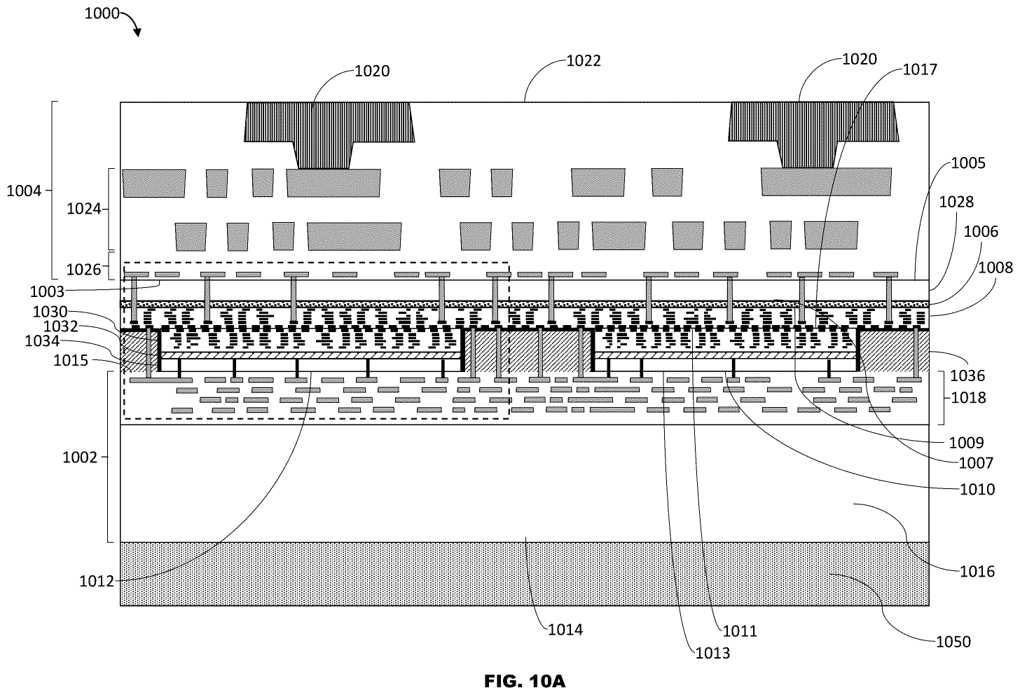

FIG. 9 illustrates an example of a semiconductor device assembly according to some embodiments. The assembly 900 can be generally similar to the assembly 100 of FIG. 2. The assembly 900 can include additional features as compared to the assembly 100. For example, a mixed signal device 904 can be disposed in the global interconnect layers 128 and/or the intermediate interconnect layers 126. The mixed signal device 904 can include contact features 908. The contact features 908 can be used to make electrical contact with the interconnect structure 108, e.g., with the intermediate interconnect layers 126 of the interconnect structure 108. The assembly 900 can include an ESD/passive device 902. The passive device 902 can be disposed in the global interconnect layers 128 and/or in the intermediate interconnect layers 126. The passive device 902 can include contact features 906. The contact features 906 can enable electrical communication with the interconnect structure 108, for example with the intermediate interconnect layers 126 of the interconnect structure 108.

In some embodiments, the passive device 902, mixed signal device 904, or both can be hybrid bonded to the intermediate interconnect layers 126 and/or the global interconnect layers 128. In some embodiments, after hybrid bonding, the passive device 902, mixed signal device 904, or both can be encapsulating with the insulating/dielectric layers of intermediate interconnect layers 126 and/or global interconnect layers 128, and metallic traces can be patterned therein.

In some embodiments, more devices, fewer devices, and/or different devices can be included in a semiconductor device assembly. For example, in some embodiments, an assembly can include one or more passive devices but may not include a mixed signal device, or an assembly can include one or more mixed signal devices but may not include a passive device.

While FIG. 9 illustrates an embodiment in which the first functional element 104 and second functional element 106 are configured for backside power delivery, it will be appreciated that it is not necessary for functional elements to be configured for backside power delivery. In some embodiments, an assembly can include at least one functional element configured for backside power delivery and at least one functional element configured for frontside power delivery.

In some embodiments, the front surface of a semiconductor device assembly can include contact features such as IO pads. In some embodiments, a thermal solution can be applied to a back surface of a semiconductor device assembly. The thermal solution can include, for example and without limitation, a heat sink, heat spreader, cold plate, and/or the like. In some embodiments, the base element may not be a major source of heat as compared with one or more functional elements. Thus, in some embodiments, it can be desirable to position the functional elements close to the back surface of the semiconductor device assembly.

In some embodiments, layers within a semiconductor device assembly can be arranged such that the functional elements are closer to the back surface of the semiconductor device assembly.

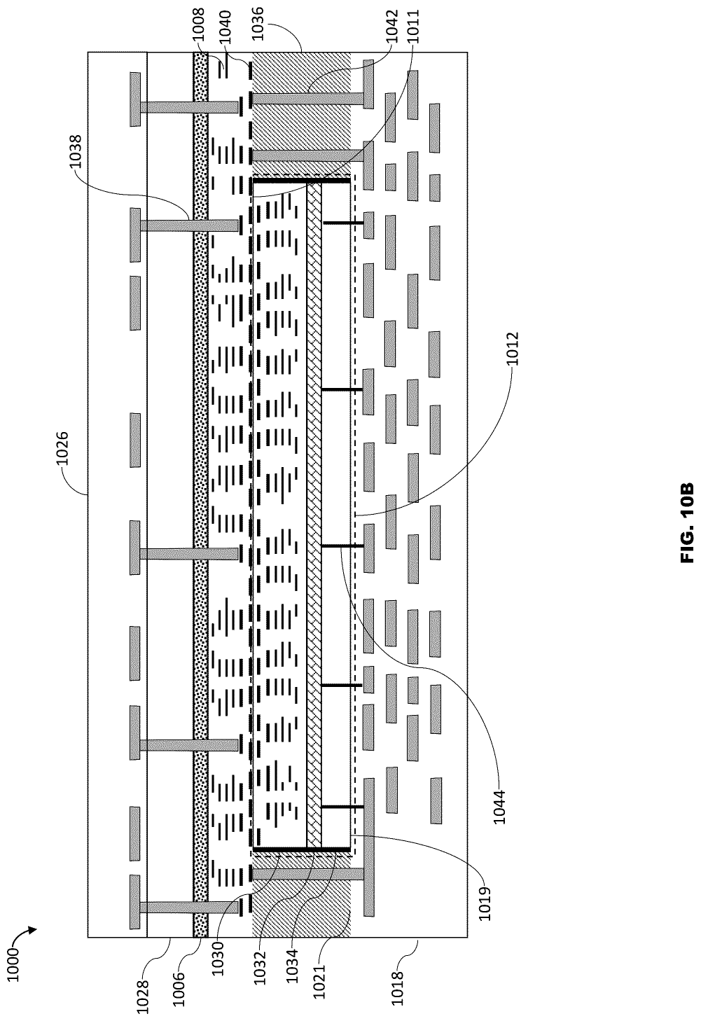

FIG. 10A illustrates an example semiconductor device assembly according to some embodiments. The assembly 1000 can share similarities with other semiconductor device assemblies described herein. However, the assembly 1000 includes various differences from other semiconductor device assemblies described herein. As shown in FIG. 10A, an assembly 1000 can include a base element 1002, base interconnect structure 1018, interconnect structure 1004, first functional element 1010, and a second functional element 1012. In FIG. 10A, the first functional element 1010 and the second functional element 1012 are configured for backside power delivery. The assembly 1000 can have a front surface 1022 and a back surface 1014. A thermal solution 1050 can be disposed on the back surface 1014. As with other embodiments described herein, it will be appreciated that the number of functional elements can vary and that some elements can be configured for frontside power delivery while other elements are configured for backside power delivery.

The base element 1002 can include a base substrate 1016 and a base interconnect structure 1018. The interconnect structure 1004 can include IO pads 1020 and/or other contact features. The interconnect structure 1004 can include global interconnects 1024 and intermediate interconnects 1026. The assembly 1000 can include a base logic substrate 1028, base logic layer 1006, and base interconnects 1008. As shown in FIG. 10A. a back surface 1003 of the interconnect structure 1004 can be disposed on a back surface 1005 of the base logic substrate 1028. The base logic layer 1006 can be disposed at or near a front surface 1007 of the base logic substrate 1028. The interconnects 1008 can be disposed on a front surface 1009 of the base logic layer 1006. The front surface 1011 of the interconnects 1008 can include contact features (e.g., contact pads, vias, etc.) on a front surface. In some embodiments, a back surface 1013 of the first functional element 1010 and second functional element 1012 can be disposed on (e.g., direct hybrid bonded to) a front surface 1015 of the base interconnect structure 1018. In some embodiments, a front surface 1017 of the first functional element 1010 and second functional element 1012 can be disposed on (e.g., hybrid bonded to) a front surface 1011 of the interconnects 1008. A front surface 1017 of the first functional element 1010 and second functional element 1012 can be disposed on the front surface 1011 of the interconnects 1008.

In some embodiments, the interconnects 1008 can be deposited over the first functional element 1010, second functional element 1012, and insulating material 1036. In some embodiments, the base logic substrate 1028 (having the base logic layer 1006 disposed on a front surface thereof) can be bonded (e.g., hybrid bonded) to the interconnects 1008. In some embodiments, the base logic substrate 1028, base logic layer 1006, and interconnects 1008 can be formed as a component that can be bonded (e.g., hybrid bonded) to the first functional element 1010, second functional element 1012, and insulating material 1036.

In some embodiments, the front surface of the interconnects 1008 and the front surface of the first functional element 1010 and/or second functional element 1012 can serve as a bonding layer. For example, the front surface of the interconnects 1008 can be bonded (e.g., hybrid bonded) to the front surface of the first functional element 1010 and/or the second functional element 1012. The back surface of the first functional element 1010, back surface of the second functional element 1012, and/or front surface of the base interconnect structure 1018 can serve as a bonding layer. For example, the back surface of the first functional element 1010 and/or the back surface of the second functional element 1012 can be bonded (e.g., hybrid bonded) to the front surface of the base interconnect structure 1018.

The first functional element 1010 and second functional element 1012 can include an interconnect region 1030, active region 1032, and substrate 1034.

FIG. 10B illustrates a detailed view of a part of the assembly 1000 of FIG. 10A, indicated by the dashed box of FIG. 10A, according to some embodiments. Power, ground, and/or signal can pass from the intermediate interconnects 1026 to the interconnects 1008 by way of vias 1038. The vias 1038 can extend from the intermediate interconnects 1026 through the base logic substrate 1028 and base logic layer 1006 to the interconnects 1008. In some embodiments, the base logic layer 1006 can be configured for frontside power delivery, which can be provided by the interconnects 1008. The interconnects 1008 can additionally or alternatively be used to route signals to and from the interconnects 1008. The interconnects 1008 can include a plurality of contact features 1040 disposed on a front surface 1011 of the interconnects 1008. The plurality of contact features 1040 can electrically connect to the interconnect region 1030 of the functional element to provide signal routing to and from the functional element 1012 (enclosed by the dashed box in FIG. 10B). The plurality of contact features 1040 can electrically connect to the base interconnect structure 1018 by way of vias 1042. The vias 1042 can pass through insulating material 1036. As described herein, the insulating material 1036 can comprise an inorganic dielectric, an organic dielectric, or both. The base interconnect structure 1018 can be electrically connected to the active region 1032 through the backside 1019 of the second functional element 1012 by way of vias 1044. While vias are illustrated in FIG. 10B, it will be appreciated that in some embodiments, the base interconnect structure 1018 can include contact features such as contact pads that can interface with contact features (e.g., contact pads, vias, etc.) of the second functional element 1012. For example, the frontside 1021 of the base interconnect structure 1018 can have contact features disposed thereon and the backside 1019 of the second functional element 1012 can have contact features disposed thereon. The contact features of the base interconnect structure 1018 and the contact features of the second functional element 1012 can be in electrical communication with one another.

### Direct Bonding

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 1108a and/or 1108b (see FIGS. 11A-11B) can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 11A and 11B schematically illustrate cross-sectional side views of first and second elements 1102, 1104 prior to and after, respectively, a process for forming a directly bonded structure, and more particularly a hybrid bonded structure, according to some embodiments. In FIG. 11B, a bonded structure 1100 comprises the first and second elements 1102 and 1104 that are directly bonded to one another at a bond interface 1118 without an intervening adhesive. Conductive features 1106a of a first element 1102 may be electrically connected to corresponding conductive features 1106b of a second element 1104. In the illustrated hybrid bonded structure 1100, the conductive features 1106a are directly bonded to the corresponding conductive features 1106b without intervening solder or conductive adhesive.

The conductive features 1106a and 1106b of the illustrated embodiment are embedded in, and can be considered part of, a first bonding layer 1108a of the first element 1102 and a second bonding layer 1108b of the second element 1104, respectively. Field regions of the bonding layers 1108a, 1108b extend between and partially or fully surround the conductive features 1106a, 1106b. The bonding layers 1108a, 1108b can comprise layers of non-conductive materials suitable for direct bonding, as described above, and the field regions are directly bonded to one another without an adhesive. The non-conductive bonding layers 1108a, 1108b can be disposed on respective front sides 1114a, 1114b of base substrate portions 1110a, 1110b.

The first and second elements 1102, 1104 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 1102, 1104, and back-end-of-line (BEOL) interconnect layers over such semiconductor portions. The bonding layers 1108a, 1108b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 1110a, 1110b, and can electrically communicate with at least some of the conductive features 1106a, 1106b. Active devices and/or circuitry can be disposed at or near the front sides 1114a, 1114b of the base substrate portions 1110a, 1110b, and/or at or near opposite backsides 1116a, 1116b of the base substrate portions 1110a, 1110b. In other embodiments, the base substrate portions 1110a, 1110b may not include active circuitry, but may instead comprise dummy substrates, passive interposers, passive optical elements (e.g., glass substrates, gratings, lenses), etc. The bonding layers 1108a, 1108b are shown as being provided on the front sides of the elements, but similar bonding layers can be additionally or alternatively provided on the back sides of the elements.

In some embodiments, the base substrate portions 1110a, 1110b can have significantly different coefficients of thermal expansion (CTEs), and bonding elements that include such different based substrate portions can form a heterogenous bonded structure. The CTE difference between the base substrate portions 1110a and 1110b, and particularly between bulk semiconductor (typically single crystal) portions of the base substrate portions 1110a, 1110b, can be greater than 5 ppm/° C. or greater than 10 ppm/° C. For example, the CTE difference between the base substrate portions 1110a and 1110b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 1110a, 1110b can comprise optoelectronic single crystal materials, including perovskite materials, that are useful for optical piezoelectric or pyroelectric applications, and the other of the base substrate portions 1110a, 1110b comprises a more conventional substrate material. For example, one of the base substrate portions 1110a, 1110b comprises lithium tantalate (LiTaO3) or lithium niobate (LiNbO3), and the other one of the base substrate portions 1110a, 1110b comprises silicon (Si), quartz, fused silica glass, sapphire, or a glass. In other embodiments, one of the base substrate portions 1110a, 1110b comprises a III-V single semiconductor material, such as gallium arsenide (GaAs) or gallium nitride (GaN), and the other one of the base substrate portions 1110a, 1110b can comprise a non-III-V semiconductor material, such as silicon (Si), or can comprise other materials with similar CTE, such as quartz, fused silica glass, sapphire, or a glass. In still other embodiments, one of the base substrate portions 1110a, 1110b comprises a semiconductor material and the other of the base substrate portions 1110a, 1110b comprises a packaging material, such as a glass, organic or ceramic substrate.

In some arrangements, the first element 1102 can comprise a singulated element, such as a singulated integrated device die. In other arrangements, the first element 1102 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 1104 can comprise a singulated element, such as a singulated integrated device die. In other arrangements, the second element 1104 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 1102, 1104 are shown, any suitable number of elements can be stacked in the bonded structure 1100. For example, a third element (not shown) can be stacked on the second element 1104, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 1102. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 1108a, 1108b, the bonding layers 1108a, 1108b can be prepared for direct bonding. Non-conductive bonding surfaces 1112a, 1112b at the upper or exterior surfaces of the bonding layers 1108a, 1108b can be prepared for direct bonding by polishing, for example, by chemical mechanical polishing (CMP). The roughness of the polished bonding surfaces 1112a, 1112b can be less than 30 Å rms. For example, the roughness of the bonding surfaces 1112a and 1112b can be in a range of about 0.1 Å rms to 15 Å rms, 0.5 Å rms to 10 Å rms, or 1 Å rms to 5 Å rms. Polishing can also be tuned to leave the conductive features 1106a, 1106b recessed relative to the field regions of the bonding layers 1108a, 1108b.

Preparation for direct bonding can also include cleaning and exposing one or both of the bonding surfaces 1112a, 1112b to a plasma and/or etchants to activate at least one of the surfaces 1112a, 1112b. In some embodiments, one or both of the surfaces 1112a, 1112b can be terminated with a species after activation or during activation (e.g., during the plasma and/or etch processes). Without being limited by theory, in some embodiments, the activation process can be performed to break chemical bonds at the bonding surface(s) 1112a, 1112b, and the termination process can provide additional chemical species at the bonding surface(s) 1112a, 1112b that alters the chemical bond and/or improves the bonding energy during direct bonding. In some embodiments, the activation and termination are provided in the same step, e.g., a plasma to activate and terminate the surface(s) 1112a, 1112b. In other embodiments, one or both of the bonding surfaces 1112a, 1112b can be terminated in a separate treatment to provide the additional species for direct bonding. In various embodiments, the terminating species can comprise nitrogen. For example, in some embodiments, the bonding surface(s) 1112a, 1112b can be exposed to a nitrogen-containing plasma. Other terminating species can be suitable for improving bonding energy, depending upon the materials of the bonding surfaces 1112a, 1112b. Further, in some embodiments, the bonding surface(s) 1112a, 1112b can be exposed to fluorine. For example, there may be one or multiple fluorine concentration peaks at or near a bond interface 1118 between the first and second elements 1102, 1104. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 1100, the bond interface 1118 between two non-conductive materials (e.g., the bonding layers 1108a, 1108b) can comprise a very smooth interface with higher nitrogen (or other terminating species) content and/or fluorine concentration peaks at the bond interface 1118. In some embodiments, the nitrogen and/or fluorine concentration peaks may be detected using various types of inspection techniques, such as SIMS techniques. The polished bonding surfaces 1112a and 1112b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 1108a and 1108b can be directly bonded to one another without an adhesive. In some embodiments, the elements 1102, 1104 are brought together at room temperature, without the need for application of a voltage, and without the need for application of external pressure or force beyond that used to initiate contact between the two elements 1102, 1104. Contact alone can cause direct bonding between the non-conductive surfaces of the bonding layers 1108a, 1108b (e.g., covalent dielectric bonding). Subsequent annealing of the bonded structure 1100 can cause the conductive features 1106a, 1106b to directly bond.

In some embodiments, prior to direct bonding, the conductive features 1106a, 1106b are recessed relative to the surrounding field regions, such that a total gap between opposing contacts after dielectric bonding and prior to anneal is less than 15 nm, or less than 10 nm. Because the recess depths for the conductive features 1106a and 1106b can vary across each element, due to process variation, the noted gap can represent a maximum or an average gap between corresponding conductive features 1106a, 1106b of two joined elements (prior to anneal). Upon annealing, the conductive features 1106a and 1106b can expand and contact one another to form a metal-to-metal direct bond.

During annealing, the conductive features 1106a, 1106b (e.g., metallic material) can expand while the direct bonds between surrounding non-conductive materials of the bonding layers 1108a, 1108b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 1106a, 1106b can comprise discrete pads, contacts, electrodes, or traces at least partially embedded in the non-conductive field regions of the bonding layers 1108a, 1108b. In some embodiments, the conductive features 1106a, 1106b can comprise exposed contact surfaces of TSVs (e.g., through silicon vias).

As noted above, in some embodiments, in the elements 1102, 1104 of FIG. 1A prior to direct bonding, portions of the respective conductive features 1106a and 1106b can be recessed below the non-conductive bonding surfaces 1112a and 1112b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 1106a, 1106b or to average depths of the recesses relative to local non-conductive field regions. Even for an individual conductive feature 1106a, 1106b, the vertical recess can vary across the feature, and so can be measured at or near the lateral middle or center of the cavity in which a given conductive feature 1106a, 1106b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 1106a, 1106b across the direct bond interface 1118 (e.g., small or fine pitches for regular arrays).

In some embodiments, a pitch p of the conductive features 1106a, 1106b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 1106a and 1106b to one of the lateral dimensions (e.g., a diameter) of the bonding pad is less than is less than 20, or less than 10, or less than 5, or less than 3 and sometimes desirably less than 2. In various embodiments, the conductive features 1106a and 1106b and/or traces can comprise copper or copper alloys, although other metals may be suitable, such as nickel, aluminum, or alloys thereof. The conductive features disclosed herein, such as the conductive features 1106a and 1106b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 1102, 1104, as shown, the orientations of one or more conductive features 1106a, 1106b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 1106b in the bonding layer 1108b (and/or at least one internal conductive feature, such as a BEOL feature) of the upper element 1104 may be tapered or narrowed upwardly, away from the bonding surface 1112b. By way of contrast, at least one conductive feature 1106a in the bonding layer 1108a (and/or at least one internal conductive feature, such as a BEOL feature) of the lower element 1102 may be tapered or narrowed downwardly, away from the bonding surface 1112a. Similarly, any bonding layers (not shown) on the backsides 1116a, 1116b of the elements 1102, 1104 may taper or narrow away from the backsides, with an opposite taper orientation relative to front side conductive features 1106a, 1106b of the same element.

As described above, in an anneal phase of hybrid bonding, the conductive features 1106a, 1106b can expand and contact one another to form a metal-to-metal direct bond. In some embodiments, the materials of the conductive features 1106a, 1106b of opposite elements 1102, 1104 can interdiffuse during the annealing process. In some embodiments, metal grains grow into each other across the bond interface 1118. In some embodiments, the metal is or includes copper, which can have grains oriented along the 111 crystal plane for improved copper diffusion across the bond interface 1118. In some embodiments, the conductive features 1106a and 1106b may include nanotwinned copper grain structure, which can aid in merging the conductive features during anneal. There is substantially no gap between the non-conductive bonding layers 1108a and 1108b at or near the bonded conductive features 1106a and 1106b. In some embodiments, a barrier layer may be provided under and/or laterally surrounding the conductive features 1106a and 1106b (e.g., which may include copper). In other embodiments, however, there may be no barrier layer under the conductive features 1106a and 1106b.

### Additional Embodiments

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

Further, while the methods and devices described herein may be susceptible to various modifications and alternative forms, specific examples thereof have been shown in the drawings and are herein described in detail. It should be understood, however, that the embodiments are not to be limited to the particular forms or methods disclosed, but, to the contrary, the embodiments are to cover all modifications, equivalents, and alternatives falling within the spirit and scope of the various implementations described and the appended claims. Further, the disclosure herein of any particular feature, aspect, method, property, characteristic, quality, attribute, element, or the like in connection with an implementation or embodiment can be used in all other implementations or embodiments set forth herein. Any methods disclosed herein need not be performed in the order recited. The methods disclosed herein may include certain actions taken by a practitioner; however, the methods can also include any third-party instruction of those actions, either expressly or by implication. The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers and should be interpreted based on the circumstances (for example, as accurate as reasonably possible under the circumstances, for example ±5%, ±10%, ±15%, etc.). For example, “about 3.5 mm” includes “3.5 mm.” Phrases preceded by a term such as “substantially” include the recited phrase and should be interpreted based on the circumstances (for example, as much as reasonably possible under the circumstances). For example, “substantially constant” includes “constant.” Unless stated otherwise, all measurements are at standard conditions including temperature and pressure.

As used herein, a phrase referring to “at least one of” a list of items refers to any combination of those items, including single members. As an example, “at least one of: A, B, or C” is intended to cover: A; B; C; A and B; A and C; B and C; and A, B, and C. Conjunctive language such as the phrase “at least one of X, Y and Z,” unless specifically stated otherwise, is otherwise understood with the context as used in general to convey that an item, term, etc. may be at least one of X, Y or Z. Thus, such conjunctive language is not generally intended to imply that certain embodiments require at least one of X, at least one of Y, and at least one of Z to each be present. The headings provided herein, if any, are for convenience only and do not necessarily affect the scope or meaning of the devices and methods disclosed herein.

Accordingly, the claims are not intended to be limited to the embodiments shown herein but are to be accorded the fairest scope consistent with this disclosure, the principles and the novel features disclosed herein.

What is claimed is:

1. A method comprising:
providing a base element having a front surface, a back surface, and base element contact features disposed on the front surface of the base element to electrically connect to a first functional element having a front surface and a back surface;
bonding the front surface of the first functional element to the front surface of the base element;
forming an insulating material on a side surface of the first functional element; and
forming an interconnect structure on the back surface of the first functional element and the insulating material,
wherein the first functional element includes power and ground electrical contact features on the back surface of the first functional element,
wherein the first functional element includes signal and electrical contact features on the front surface of the first functional element, and
wherein the interconnect structure is electrically connected to the power and ground electrical contact features of the first functional element.

2. The method of claim 1, wherein bonding the front surface of the first functional element to the front surface of the base element comprises hybrid bonding the front surface of the first functional element to the front surface of the base element.

3. The method of claim 1, wherein the first functional element further comprises:
a first functional element active region disposed near the front surface of the first functional element,
wherein the interconnect structure delivers power or ground to the first functional element active region via the back surface of the first functional element.

4. The method of claim 1, further comprising:
bonding a second functional element to the front surface of the base element, the second functional element having a front surface and a back surface, the second functional element bonded to the front surface of the base element via the front surface of the second functional element.

5. The method of claim 4, wherein the front surface of the first functional element is hybrid bonded to the front surface of the base element, and wherein the front surface of the second functional element is hybrid bonded to the front surface of the base element.

6. The method of claim 4, wherein the second functional element electrically connects to power or ground via the front surface of the second functional element.

7. The method of claim 4, wherein the second functional element comprises power and ground electrical connections disposed on the back surface of the second functional element, and
wherein the second functional element comprises signal and electrical connections disposed on the front surface of the second functional element.

8. The method of claim 1, wherein the interconnect structure further comprises a mixed signal element.

9. The method of claim 1, further comprising:
placing a heat spreader in thermal communication with the back surface of the base element.

10. The method of claim 4, wherein the base element comprises a base die interconnect structure having an integrated voltage regulator.

11. The method of claim 10, wherein the first functional element receives power directly from the interconnect structure at a first voltage,
wherein the second functional element receives power at a second voltage different from the first voltage, and
wherein the second functional element receives power that is routed from the interconnect structure to the integrated voltage regulator.

12. A method comprising:
providing a base element comprising:
a base substrate having a frontside with active circuitry and a backside opposite the frontside; and
a first bonding layer disposed on the frontside of the base substrate including a contact feature to convey an electrical signal to the active circuitry;
providing a first functional element comprising:
a first semiconductor substrate having a frontside with active circuitry and a backside opposite the frontside;
a first contact feature disposed on a back surface of the first functional element and configured to connect to power or ground; and
a second bonding layer disposed on the frontside of the first semiconductor substrate; and
hybrid bonding the first bonding layer of the base element to the second bonding layer of the first functional element.

13. The method of claim 12, further comprising forming an insulating material disposed along a side surface of the first functional element and on the first bonding layer.

14. The method of claim 12, further comprising forming an interconnect structure disposed on the back surface of the first functional element and electrically connected to the first contact feature.

15. The method of claim 14, wherein the interconnect structure comprises an intermediate interconnect layer and a global interconnect layer,
wherein the intermediate interconnect layer is disposed near a back surface of the interconnect structure,
wherein the global interconnect layer is disposed on the intermediate interconnect layer nearer to a front surface of the interconnect structure than the intermediate interconnect layer, and
wherein the intermediate interconnect layer is in electrical communication with the global interconnect layer.

16. The method of claim 12, further comprising providing a second functional element comprising a second semiconductor substrate having a frontside with active circuitry and a backside opposite the frontside.

17. The method of claim 16, further comprising hybrid bonding the backside of the second functional element to the first bonding layer, and
wherein the second functional element comprises a second contact feature disposed on a front surface of the second functional element.

18. A method comprising:
providing a base element comprising:
a base substrate having a frontside and a backside opposite the frontside; and
a first bonding layer disposed on the frontside of the base substrate;
providing a first functional element comprising:
a first semiconductor substrate having a frontside with active circuitry and a backside opposite the frontside; and
a second bonding layer disposed on the frontside of the first semiconductor substrate, the backside of the first semiconductor substrate comprising a first contact feature to connect to power or ground;
providing a second functional element comprising:
a second semiconductor substrate having a frontside with active circuitry and a backside opposite the frontside;
hybrid bonding the first bonding layer to the second bonding layer; and
hybrid bonding the second functional element to the first bonding layer.

19. The method of claim 18, further comprising hybrid bonding the backside of the second semiconductor substrate to the base element, wherein the second functional element comprises a second contact feature disposed on the frontside of the second semiconductor substrate to connect to power or ground.

20. The method of claim 18, further comprising hybrid bonding the frontside of the second functional element to the first bonding layer, wherein the backside of the second semiconductor substrate comprises a second contact feature to connect to power or ground.

21. The method of claim 18, wherein the first bonding layer includes a contact feature to convey an electrical signal to the active circuitry.

22. The method of claim 18, further comprising forming an insulating material disposed along a side surface of the first functional element and on the first bonding layer.

23. The method of claim 18, further comprising forming an interconnect structure disposed on the backside of the first semiconductor substrate and electrically connected to the first contact feature.

24. The method of claim 23, wherein the interconnect structure comprises a redistribution layer.
